(19) United States
(12) Patent Application Publication
(10) Pub. No.: US 2017/0280594 A1
(43) Pub. Date: Sep. 28, 2017

(54) COOLING DEVICE, CONTROL METHOD AND CONTROL PROGRAM FOR SAME, AND STORAGE MEDIUM

(71) Applicant: NEC Corporation, Tokyo (JP)

(72) Inventors: Masanori SATO, Tokyo (JP); Kenichi INABA, Tokyo (JP); Minoru YOSHIKAWA, Tokyo (JP); Akira SHOUJIGUCHI, Tokyo (JP); Masaki CHIBA, Tokyo (JP); Arihiro MATSUNAGA, Tokyo (JP)

(73) Assignee: NEC Corporation, Tokyo (JP)

(21) Appl. No.: 15/504,074

(22) PCT Filed: Aug. 20, 2015
(86) PCT No.: PCT/JP2015/004161

§ 371 Date: Feb. 15, 2017

(30) Foreign Application Priority Data
Aug. 26, 2014 (JP) 2014-171528

(51) Int. Cl. H05K 7/20; G05B 15/02

(52) U.S. Cl. CPC H05K 7/20836; G05B 15/02; H05K 7/20745; H05K 7/20827

(57) ABSTRACT

A rack louver 120 controls an air flow of outside air external to an enclosure 10 taken into the enclosure 10, flowing from an inlet 20 to an outlet 30 in a rack 60. An outlet louver 130 controls an air flow of inside air internal to the enclosure 10 flowing out from the outlet 30 to outside the enclosure 10. A system control unit 150 adjusts motive power of a blowing unit 40, a degree of opening of the rack louver 120, and a degree of opening of the outlet louver 130 in accordance with an outside-air temperature measured by an outside-air temperature sensor 50 and electronic equipment power consumption measured by a power sensor 100. Consequently, electronic equipment in the rack can be cooled with higher energy efficiency while suppressing temperature rise in the electronic equipment.

### TECHNICAL FIELD

The present invention relates to a cooling device and the like, and, for example, relates to a cooling device and the like in a data center and the like cooling electronic equipment in a rack provided in a container.

### BACKGROUND ART

Recent development of cloud services has led to increasing an amount of information processing. In order to process such a vast amount of information, data centers are installed and operated in a plurality of regions.

An amount of information processing has been gradually increasing in a data center installed in each region as well, and heating density in a data center continues to increase. Accordingly, at a common data center, cooling facilities are installed in the data center to adjust the temperature in the data center to a proper level.

A common data center is constructed by intensively installing many pieces of hardware including servers and communication equipment at a huge site. Accordingly, it takes a long period of time to complete a data center, and a service may not be provided until completion of the data center.

Consequently, a container-type data center has been developed and put to actual use. The container-type data center is a container in which a predetermined number of racks are mounted and are functioning as a module.

PTL 1 discloses an example of a container-type data center as a module-type data center. In the module-type data center described in PTL 1, a rack 33 housing electronic equipment, a blower 32, and a temperature sensor 53 are housed in a container (enclosure) 30. The container 30 is provided with an inlet 31a and an outlet 31b. The blower 32 takes outside air external to the container 30 into the container 30 through the inlet 31a to cool the electronic equipment in the rack 33 in the container 30. Further, in the container 30, a warm-air outlet 33a is provided on an upper part of the rack 33. Then, when a measured temperature of the temperature sensor 53 is higher than a predetermined temperature, a degree of opening of the warm-air outlet 33a is decreased. Consequently, an amount of warm air returning from inside the rack 33 to an outside-air introduction unit 41 through a warm-air circulation path 44 decreases, and a temperature in a cold aisle 42 drops. On the other hand, when a measured temperature of the temperature sensor 53 is lower than a predetermined temperature, a degree of opening of the warm-air outlet 33a is increased. Consequently, an amount of warm air returning from inside the rack 33 to the outside-air introduction unit 41 through the warm-air circulation path 44 increases, and the temperature in the cold aisle 42 rises. Thus, in the technology described in PTL 1, the temperature taken into the rack 33 is controlled to be within a temperature range guaranteeing operation of electronic equipment mounted in the rack 33.

PTL 2 proposes an attempt to control power consumption of an entire data center by use of power usage effectiveness (PUE) of the data center. PUE is expressed as PUE=(power consumption of the entire data center)/(power consumption of electronic equipment in a rack)=[(power consumption of the electronic equipment in the rack)+(power consumption of incidental equipment such as air conditioning equipment)]/(power consumption of the electronic equipment in the rack).

The power consumption of the electronic equipment in the rack includes electric power consumed by a server, a storage, a router, an administrative terminal, and the like. Further, the power consumption of the incidental equipment such as air conditioning equipment includes electric power consumed by a cooling device such as air conditioning equipment, lighting, a monitoring device, a power system, and the like.

For example, when PUE is equal to 2.0, half of electric power consumed in an entire data center becomes power consumption of electronic equipment. As PUE becomes smaller, a ratio of power consumption used by equipment other than electronic equipment becomes smaller.

PTLs 3 to 5 also disclose technologies related to the present invention.

### CITATION LIST

### Patent Literature

[PTL 1] Japanese Unexamined Patent Application Publication No. 2013-210715

[PTL 2] Japanese Unexamined Patent Application Publication No. 2012-21711

[PTL 3] Japanese Unexamined Patent Application Publication No. 2014-72411

[PTL 4] Japanese Unexamined Patent Application Publication No. 2012-212720

[PTL 5] Japanese Unexamined Patent Application Publication No. 2002-196840

### SUMMARY OF INVENTION

### Technical Problem

However, the technology described in PTL 1 has a problem that, although the temperature in the rack 33 is controlled to be within a predetermined range, power consumption of the entire container-type data center is not considered.

In accordance with a recent trend toward promotion of energy saving, each data center provider tends to focus on decreasing PUE, as is the case with the technology described in PTL 2. In the PUE, electric power of a fan on a server (electronic equipment) that should be primarily factored in as a cooling device is factored into power consumption of the electronic equipment. Consequently, there is a problem that a data center appearing efficient at first is actually not efficient, thus causing misinterpretation. That is to say, PUE in the technology described in PTL 2 additionally includes electric power of a fan on a server, contributing to cooling, in power consumption of the entire electronic equipment. Consequently, there is a problem that, when electric power of the fan on the server increases due to temperature rise in the server, PUE becomes very large although the electric power of the fan on the server contributes to cooling.

The present invention is made in view of such a situation, and an object of the present invention is to provide a cooling device that is able to cool electronic equipment in a rack with higher energy efficiency while suppressing temperature rise in the electronic equipment.

### Solution to Problem

A cooling device according to the present invention includes an enclosure including an inlet and an outlet, a blowing unit being provided in the enclosure, taking outside air external to the enclosure into the enclosure through the inlet, and discharging inside air internal to the enclosure to outside the enclosure through the outlet, an outside-air temperature sensor measuring a temperature of outside air external to the enclosure as an outside-air temperature, an electronic equipment housing enclosure being provided between the inlet and the outlet in the enclosure and housing electronic equipment, an electronic equipment fan being provided in the electronic equipment, taking outside air external to the electronic equipment housing enclosure into the electronic equipment housing enclosure, and discharging inside air internal to the electronic equipment housing enclosure to outside the electronic equipment housing enclosure, a power sensor measuring power consumption of the electronic equipment in the electronic equipment housing enclosure as electronic equipment power consumption, a first opening-closing mechanism unit being provided between the inlet and the outlet in the enclosure and on an upper side of the electronic equipment housing enclosure in the enclosure so as to separate air taken into the electronic equipment housing enclosure and air discharged from the electronic equipment housing enclosure, and controlling an air flow of outside air external to the enclosure taken into the electronic equipment housing enclosure, flowing from the inlet to the outlet, a second opening-closing mechanism unit being provided on the outlet and controlling an air flow of inside air internal to the enclosure, flowing out from the outlet to outside the enclosure, and a system control unit adjusting motive power of the blowing unit, a degree of opening of the first opening-closing mechanism unit, and a degree of opening of the second opening-closing mechanism unit in accordance with the outside-air temperature measured by the outside-air temperature sensor and the electronic equipment power consumption measured by the power sensor.

A control method of a cooling device according to the present invention is a control method of a cooling device including an enclosure including an inlet and an outlet, a blowing unit being provided in the enclosure, taking outside air external to the enclosure into the enclosure through the inlet, and discharging inside air internal to the enclosure to outside the enclosure through the outlet, an outside-air temperature sensor measuring a temperature of outside air external to the enclosure as an outside-air temperature, an electronic equipment housing enclosure being provided between the inlet and the outlet in the enclosure and housing electronic equipment, an electronic equipment fan being provided in the electronic equipment, taking outside air external to the electronic equipment housing enclosure into the electronic equipment housing enclosure, and discharging inside air internal to the electronic equipment housing enclosure to outside the electronic equipment housing enclosure, a power sensor measuring power consumption of the electronic equipment in the electronic equipment housing enclosure as electronic equipment power consumption, a first opening-closing mechanism unit being provided between the inlet and the outlet in the enclosure and on an upper side of the electronic equipment housing enclosure in the enclosure so as to separate air taken into the electronic equipment housing enclosure and air discharged from the electronic equipment housing enclosure, and controlling an air flow of outside air external to the enclosure taken into the electronic equipment housing enclosure, flowing from the inlet to the outlet, and a second opening-closing mechanism unit being provided on the outlet and controlling an air flow of inside air internal to the enclosure, flowing out from the outlet to outside the enclosure, the method including adjusting motive power of the blowing unit, a degree of opening of the first opening-closing mechanism unit, and a degree of opening of the second opening-closing mechanism unit in accordance with the outside-air temperature measured by the outside-air temperature sensor and the electronic equipment power consumption measured by the power sensor.

A storage medium according to the present invention is a storage medium storing a control program of a cooling device including an enclosure including an inlet and an outlet, a blowing unit being provided in the enclosure, taking outside air external to the enclosure into the enclosure through the inlet, and discharging inside air internal to the enclosure to outside the enclosure through the outlet, an outside-air temperature sensor measuring a temperature of outside air external to the enclosure as an outside-air temperature, an electronic equipment housing enclosure being provided between the inlet and the outlet in the enclosure and housing electronic equipment, an electronic equipment fan being provided in the electronic equipment, taking outside air external to the electronic equipment housing enclosure into the electronic equipment housing enclosure, and discharging inside air internal to the electronic equipment housing enclosure to outside the electronic equipment housing enclosure, a power sensor measuring power consumption of the electronic equipment in the electronic equipment housing enclosure as electronic equipment power consumption, a first opening-closing mechanism unit being provided between the inlet and the outlet in the enclosure and on an upper side of the electronic equipment housing enclosure in the enclosure so as to separate air taken into the electronic equipment housing enclosure and air discharged from the electronic equipment housing enclosure, and controlling an air flow of outside air external to the enclosure taken into the electronic equipment housing enclosure, flowing from the inlet to the outlet, and a second opening-closing mechanism unit being provided on the outlet and controlling an air flow of inside air internal to the enclosure, flowing out from the outlet to outside the enclosure, the control program causing a computer to perform control of adjusting motive power of the blowing unit, a degree of opening of the first opening-closing mechanism unit, and a degree of opening of the second opening-closing mechanism unit in accordance with the outside-air temperature measured by the outside-air temperature sensor and the electronic equipment power consumption measured by the power sensor.

### Advantageous Effects of Invention

A cooling device and the like according to the present invention are able to cool electronic equipment in a rack with higher energy efficiency while suppressing temperature rise in the electronic equipment.

### BRIEF DESCRIPTION OF DRAWINGS

FIG. 1 is a cross-sectional view illustrating a configuration of a cooling device according to a first exemplary embodiment of the present invention.

FIG. 2 is a transparent perspective view transparently illustrating a configuration of the cooling device according to the first exemplary embodiment of the present invention.

FIG. 3 is a cross-sectional view illustrating a configuration of a rack louver and an outlet louver.

FIG. 4 is a block diagram illustrating a configuration of an electric circuit in the cooling device according to the first exemplary embodiment of the present invention.

FIG. 5 is an operational flowchart of the cooling device according to the first exemplary embodiment of the present invention.

FIG. 6A is an operational flowchart for controlling a warm-air circulation amount in the cooling device according to the first exemplary embodiment of the present invention.

FIG. 6B is an operational flowchart for controlling a warm-air circulation amount in the cooling device according to the first exemplary embodiment of the present invention.

FIG. 6C is an operational flowchart for controlling a warm-air circulation amount in the cooling device according to the first exemplary embodiment of the present invention.

FIG. 7 is a cross-sectional view illustrating a configuration of a cooling device according to a second exemplary embodiment of the present invention.

FIG. 8 is a transparent perspective view transparently illustrating a configuration of the cooling device according to the second exemplary embodiment of the present invention.

FIG. 9 is a block diagram illustrating a configuration of an electric circuit in the cooling device according to the second exemplary embodiment of the present invention.

FIG. 10 is an operational flowchart of the cooling device according to the second exemplary embodiment of the present invention.

FIG. 11 is a cross-sectional view illustrating a configuration of a cooling device according to a third exemplary embodiment of the present invention.

FIG. 12 is a transparent perspective view transparently illustrating a configuration of the cooling device according to the third exemplary embodiment of the present invention.

FIG. 13 is a block diagram illustrating a configuration of an electric circuit in the cooling device according to the third exemplary embodiment of the present invention.

FIG. 14 is an operational flowchart of the cooling device according to the third exemplary embodiment of the present invention.

### DESCRIPTION OF EMBODIMENTS

### First Exemplary Embodiment

A configuration of a cooling device 1000 according to a first exemplary embodiment of the present invention will be described.

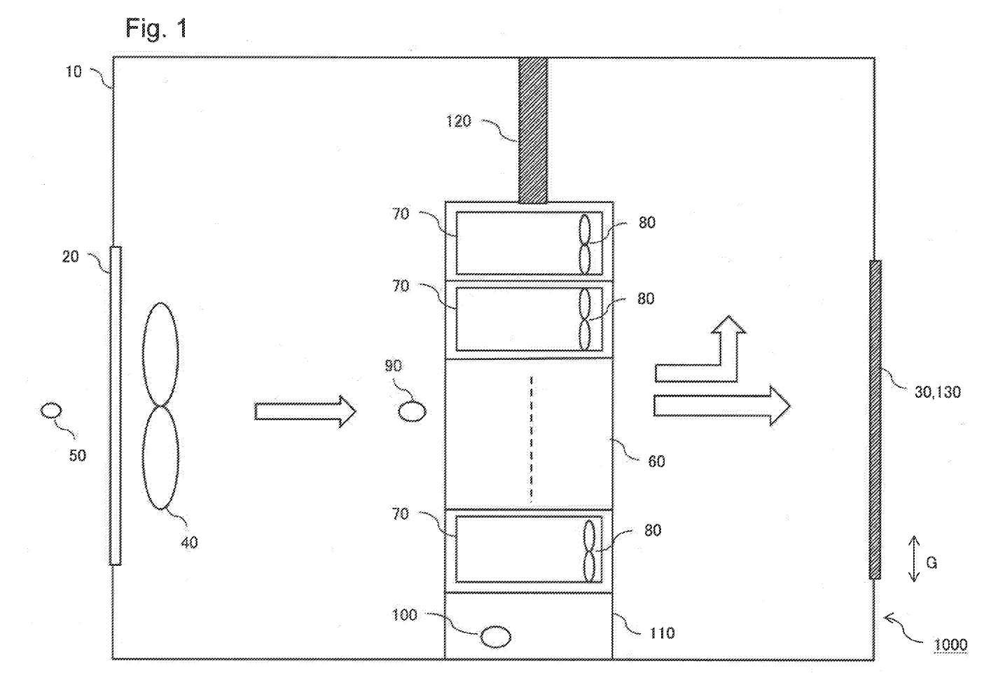

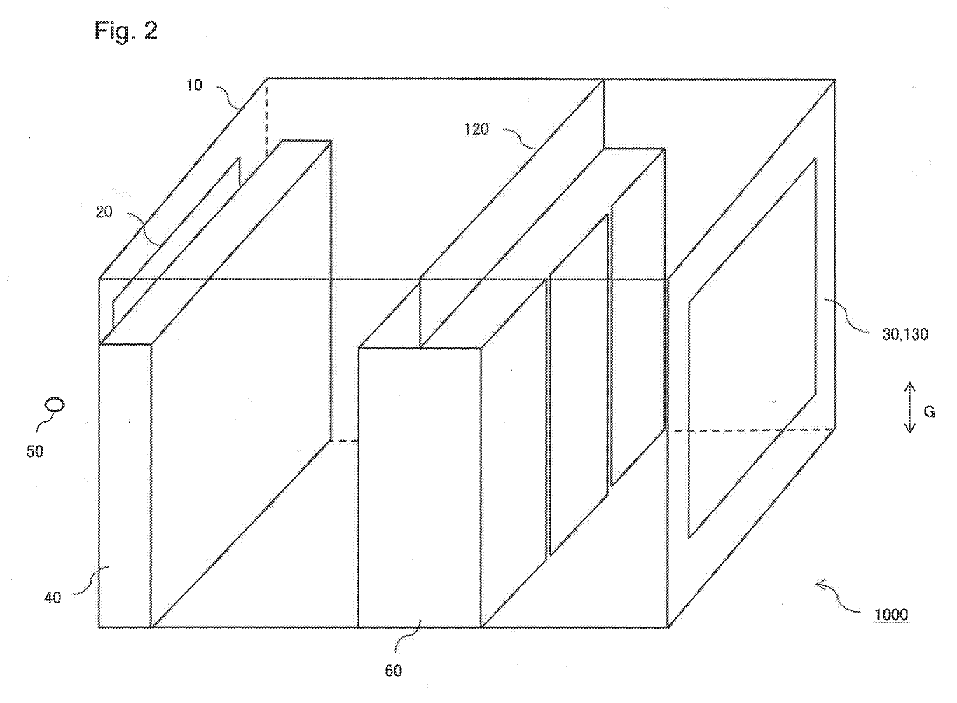

FIG. 1 is a cross-sectional view illustrating a configuration of the cooling device 1000. FIG. 2 is a transparent perspective view transparently illustrating a configuration of the cooling device 1000. A vertical direction G is illustrated in FIGS. 1 and 2.

As illustrated in FIGS. 1 and 2, the cooling device 1000 includes an enclosure 10, an inlet 20, an outlet 30, a blowing unit 40, an outside-air temperature sensor 50, a rack 60, electronic equipment 70, an electronic equipment fan 80, a rack inlet temperature sensor 90, a power sensor 100, an electronic equipment accessory 110, a rack louver 120, and an outlet louver 130. The cooling device 1000 is also called a module-type data center. The rack 60 corresponds to the electronic equipment housing enclosure according to the present invention. The rack louver 120 corresponds to the first opening-closing mechanism unit according to the present invention. The outlet louver 130 corresponds to the second opening-closing mechanism unit according to the present invention.

As illustrated in FIGS. 1 and 2, the enclosure 10 is formed in a cuboid shape. The inside of the enclosure 10 is hollow. Various types of equipment such as the rack 60 are housed in the enclosure 10. A member with high thermal conductivity (e.g. aluminum or an aluminum alloy) is used as a material of the enclosure 10. For example, the enclosure 10 is a container.

As illustrated in FIGS. 1 and 2, the inlet 20 is provided on a side surface of the enclosure 10. The inlet 20 is an opening for causing outside air external to the enclosure 10 to be taken (to flow) into the enclosure 10. A rainwater infiltration prevention plate for preventing rainwater infiltration, an insect-proof plate for preventing invasion of insects, a filter for preventing entry of dirt and dust, and the like are used for the inlet 20. The inlet 20 is preferably placed so as to face the outlet 30. Thus, outside air taken in from the inlet 20 flows smoothly to the outlet 30 through the rack 60.

As illustrated in FIGS. 1 and 2, the outlet 30 is provided on a side surface of the enclosure 10. The outlet 30 is an opening for causing inside air internal to the enclosure to be discharged (to flow out) to outside the enclosure. The outlet 30 is preferably placed so as to face the inlet 20. Thus, outside air taken in from the inlet 20 flows smoothly to the outlet 30 through the rack 60.

As illustrated in FIGS. 1 and 2, the blowing unit 40 is provided in the enclosure 10. The blowing unit 40 is provided between the inlet 20 and the rack 60. The blowing unit 40 takes outside air external to the enclosure 10 into the enclosure 10 through the inlet 20 and also discharges inside air internal to the enclosure 10 to outside the enclosure 10 through the outlet 30. The blowing unit 40 is preferably placed so as to face the inlet 20. Thus, the blowing unit 40 is able to efficiently take in outside air external to the enclosure 10 from the inlet 20.

As illustrated in FIGS. 1 and 2, the outside-air temperature sensor 50 is provided outside the enclosure 10 and near the inlet 20. The outside-air temperature sensor 50 measures a temperature of outside air external to the enclosure 10 as an outside-air temperature.

As illustrated in FIGS. 1 and 2, a plurality of racks 60 are provided between the inlet 20 and the outlet 30 in the enclosure 10. Each of the plurality of racks 60 houses electronic equipment 70. The plurality of racks 60 are preferably placed so as to face the inlet 20 and the outlet 30. Thus, outside air taken in from the inlet 20 flows smoothly to the outlet 30 through the rack 60.

As illustrated in FIG. 1, the electronic equipment 70 is housed in each rack 60. For example, the electronic equipment 70 is a server (calculating equipment).

As illustrated in FIG. 1, the electronic equipment fan 80 is provide in each rack 60. Further, the electronic equipment fan 80 is provided in the electronic equipment 70. The electronic equipment fan 80 causes outside air external to the rack 60 to be taken into the rack 60 and also discharges inside air external to the rack 60 to outside the rack 60. Thus, the electronic equipment 70 housed in the rack 60 is cooled by outside air taken in by the electronic equipment fan 80. In FIG. 1, the inlet (unillustrated) of the rack 60 is provided at the left end of the page space, and the outlet (unillustrated) of the rack 60 is provided at the right end of the page space.

As illustrated in FIG. 1, the rack inlet temperature sensor 90 is provided on the inlet side of the rack 60. The rack inlet temperature sensor 90 measures a temperature near the inlet on the rack 60. The rack inlet temperature sensor 90 is not an essential requirement of the present invention, and therefore may be omitted.

As illustrated in FIG. 1, the power sensor 100 is provided in proximity to the rack 60. The power sensor 100 measures power consumption of the electronic equipment 70 in the rack 60 as electronic equipment power consumption.

As illustrated in FIG. 1, the electronic equipment accessory 110 is housed in the rack 60. For example, the electronic equipment accessory 110 is a storage, a power source, a cable, and the like for electronic equipment.

As illustrated in FIGS. 1 and 2, the rack louver 120 is provided in an openable and closable manner between the inlet 20 and the outlet 30 in the enclosure 10 and on an upper side, in the vertical direction G, of the rack 60 in the enclosure 10 so as to separate air taken into the rack 60 and air discharged from the rack 60. By adjusting a degree of opening, the rack louver 120 controls an air flow of outside air external to the enclosure 10 taken into the rack 60 by the blowing unit 40, flowing from the inlet 20 to the outlet 30 on the upper side, in the vertical direction G, of the rack. A detailed configuration of the rack louver 120 will be described later along with description of a configuration of the outlet louver 130.

As illustrated in FIGS. 1 and 2, the outlet louver 130 is provided in an openable and closable manner on the outlet 30. By adjusting a degree of opening, the outlet louver 130 controls an air flow of inside air internal to the enclosure 10 discharged from the outlet 30 to outside the enclosure 10.

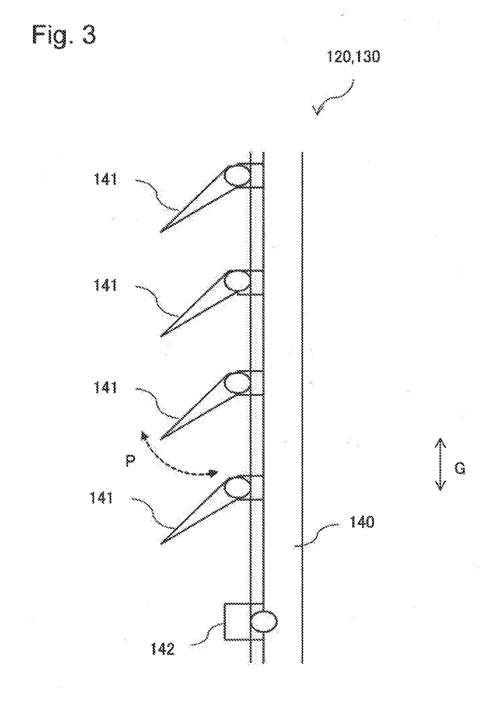

Configurations of the rack louver 120 and the outlet louver 130 will be described. FIG. 3 is a cross-sectional view illustrating a configuration of the rack louver 120 and the outlet louver 130. A vertical direction G is illustrated in FIG. 3.

As illustrated in FIG. 3, each of the rack louver 120 and the outlet louver 130 includes a louver system 140.

The louver system 140 includes a plurality of blades 141 and a louver actuation unit 142. The plurality of blades 141 are arranged along the vertical direction G. Each of the plurality of blades 141 is provided so as to extend along a direction perpendicular to the vertical direction G. The plurality of blades 141 revolve around an end part in a direction of an arrow P (e.g. between 0 degrees to 90 degrees). Thus, the rack louver 120 and the outlet louver 130 are opened and closed.

The louver actuation unit 142 actuates a plurality of blades 141. That is to say, the louver actuation unit 142 revolves a plurality of blades 141. Thus, a flow of air (air current) passing the rack louver 120 and the outlet louver 130 can be blocked and passed.

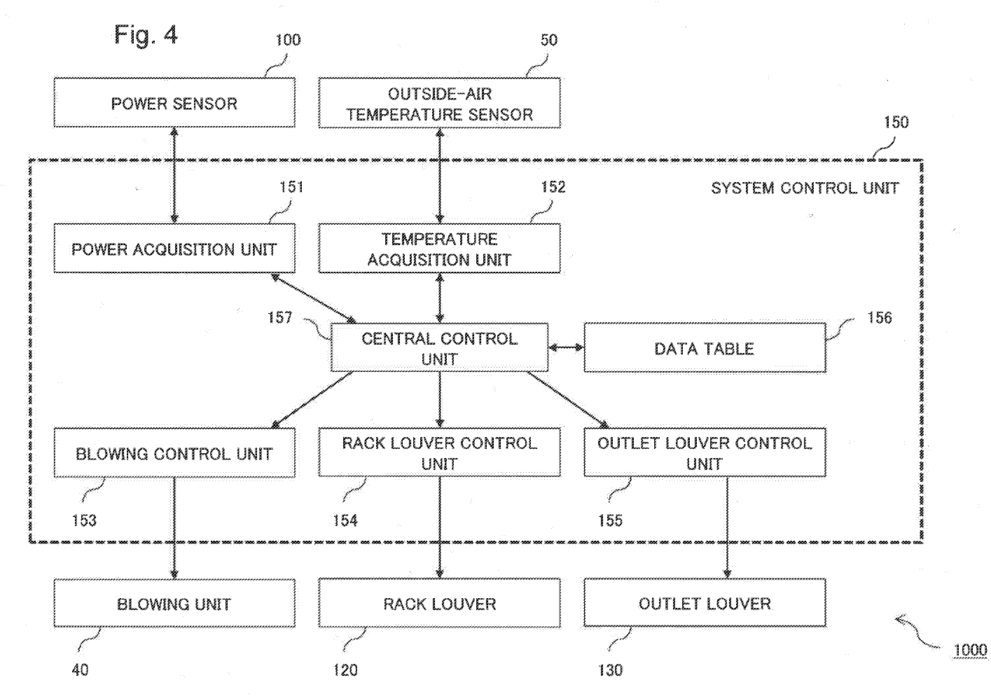

Next, a configuration of an electric circuit in the cooling device 1000 will be described. FIG. 4 is a block diagram illustrating a configuration of the electric circuit in the cooling device 1000. Further, a direction of an arrow in the drawing represents an example and does not limit a signal direction between blocks.

As illustrated in FIG. 4, the cooling device 1000 includes a system control unit 150. The system control unit 150 is connected to the power sensor 100, the outside-air temperature sensor 50, the blowing unit 40, the rack louver 120, and the outlet louver 130. It is assumed that the system control unit 150 is provided in a local server in the cooling device 1000. However, the system control unit 150 may be provided on a cloud.

The system control unit 150 includes a power acquisition unit 151, a temperature acquisition unit 152, a blowing control unit 153, a rack louver control unit 154, an outlet louver control unit 155, a data table 156, and a central control unit 157. The system control unit 150 adjusts motive power of the blowing unit 40, a degree of opening of the rack louver 120, and a degree of opening of the outlet louver 130 in accordance with an outside-air temperature measured by the outside-air temperature sensor 50 and electronic equipment power consumption measured by the power sensor 100.

The power acquisition unit 151 is connected to the power sensor 100 and the central control unit 157. The power acquisition unit 151 acquires electronic equipment power consumption (power consumption of the electronic equipment 70 in the rack 60) measured by the power sensor 100 from the power sensor 100. Further, the power acquisition unit 151 outputs electronic equipment power consumption to the central control unit 157.

The temperature acquisition unit 152 is connected to the outside-air temperature sensor 50 and the central control unit 157. The temperature acquisition unit 152 acquires an outside-air temperature (a temperature of outside air external to the enclosure 10) measured by the outside-air temperature sensor 50 from the outside-air temperature sensor 50. Further, the temperature acquisition unit 152 outputs an outside-air temperature to the central control unit 157.

The blowing control unit 153 is connected to the blowing unit 40 and the central control unit 157. The blowing control unit 153 controls motive power (e.g. a revolving speed) of the blowing unit 40 in accordance with an instruction from the central control unit 157.

The rack louver control unit 154 is connected to the rack louver 120 and the central control unit 157. The rack louver control unit 154 controls a degree of opening of the rack louver 120 in accordance with an instruction from the central control unit 157.

The outlet louver control unit 155 is connected to the outlet louver 130 and the central control unit 157. The outlet louver control unit 155 controls a degree of opening of the outlet louver 130 in accordance with an instruction from the central control unit 157.

The data table 156 is connected to the central control unit 157. The data table 156 stores motive power (e.g. a revolving speed) of the blowing unit 40, a degree of opening of the rack louver 120, and a degree of opening of the outlet louver 130 that are calculated, in relation to an outside-air temperature measured by the outside-air temperature sensor 50 and electronic equipment power consumption measured by the power sensor 100, so as to minimize power usage effectiveness (PUE′) expressed by equation (1) below.

power usage effectiveness (PUE′)=[(power consumption of the electronic equipment−power consumption of the electronic equipment fan)+(power consumption of the blowing unit+power consumption of the electronic equipment fan)]/(power consumption of the electronic equipment−power consumption of the electronic equipment fan) equation (1)

Two preparation methods of the data table 156 will be described below.

A first data table preparation method prepares the data table 156 by obtaining degrees of influence of motive power (e.g. a revolving speed) of the blowing unit 40, a degree of opening of the rack louver 120, and a degree of opening of the outlet louver 130 on power usage effectiveness (PUE′) expressed by equation (1), by performing a preliminary power measurement experiment (utilizing design of experiments) on an outside-air introduction-type cooling device (data center). Specifically, multiple regression analysis is performed at a certain outside-air temperature with motive power of the blowing unit 40, a degree of opening of the rack louver 120, and a degree of opening of the outlet louver 130 as explanatory variables and PUE′ as a response variable. Respective coefficients of the obtained explanatory variables become respective degrees of influence on PUE′.

Respective numerical values obtained in the preparation of the data table 156 are optimally determined so as to minimize cooling power consumption while maintaining a guaranteed intake air temperature range (to be described later) of the electronic equipment 70. The guaranteed intake air temperature range of the electronic equipment 70 refers to a temperature range of heat taken into the electronic equipment 70 and, at the same time, a temperature range guaranteeing operation of the electronic equipment 70. More specifically, a temperature near the inlet on the rack 60 is measured by the rack inlet temperature sensor 90, and adjustment is performed so that a measured temperature of the rack inlet temperature sensor 90 is included within the guaranteed intake air temperature range of the electronic equipment 70 (e.g. a server).

A second data table preparation method appropriately prepares the data table 156 by use of online learning being a type of machine learning, or the like. In this method, the data table 156 does not need to be prepared in advance. Specifically, motive power (e.g. a revolving speed) of the blowing unit 40, a degree of opening of the rack louver 120, and a degree of opening of the outlet louver 130 are changed at a predetermined outside-air temperature and predetermined electronic equipment power consumption, while satisfying a guaranteed intake air temperature range of the electronic equipment 70. The data table 156 is prepared by appropriately causing learning by changing the degrees of opening so that power usage effectiveness (PUE′) expressed by equation (1) is minimized. When using the second data table preparation method, the cooling device 1000 is not able to operate with high power efficiency until a learning result converges. However, after a certain learning time elapses and data on motive power (e.g. a revolving speed) of the blowing unit 40, a degree of opening of the rack louver 120, a degree of opening of the outlet louver 130, and the like converge, a data table 156 giving the best power efficiency of the cooling device 1000 at a certain outside-air temperature and certain electronic equipment power consumption is prepared.

The central control unit 157 is connected to the power acquisition unit 151, the temperature acquisition unit 152, the blowing control unit 153, the rack louver control unit 154, the outlet louver control unit 155, and the data table 156. The central control unit 157 outputs an instruction signal and the like to the power acquisition unit 151, the temperature acquisition unit 152, the blowing control unit 153, the rack louver control unit 154, the outlet louver control unit 155, and the data table 156.

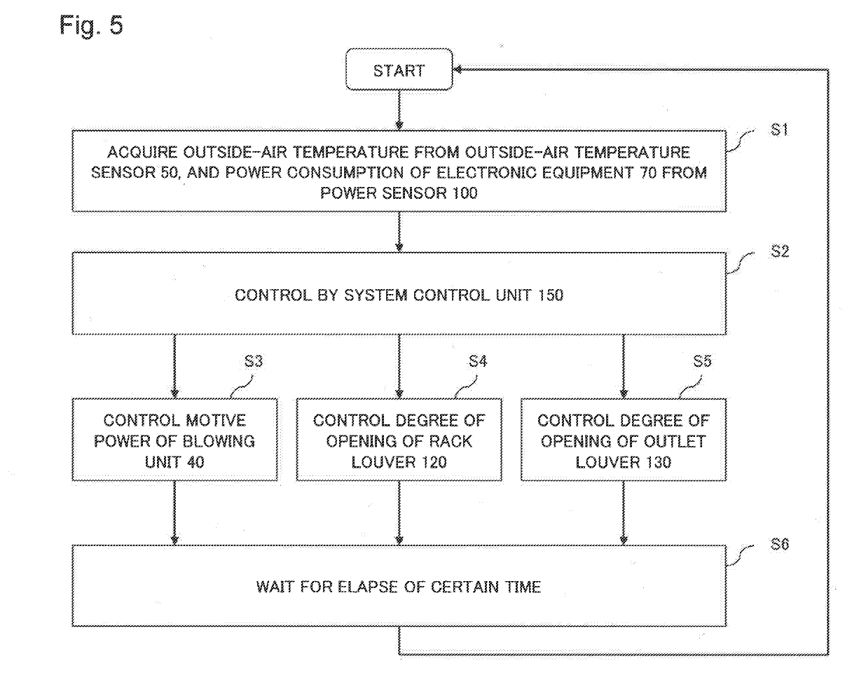

Next, an operation of the cooling device 1000 will be described. FIG. 5 is an operational flowchart of the cooling device 1000.

As indicated in FIG. 5, first, the system control unit 150 acquires an outside-air temperature from the outside-air temperature sensor 50, and electronic equipment power consumption from the power sensor 100 (Step [hereinafter denoted as S] 1).

More specifically, the temperature acquisition unit 152 in the system control unit 150 acquires an outside-air temperature (a temperature of outside air external to the enclosure 10) measured by the outside-air temperature sensor 50 from the outside-air temperature sensor 50. Then, the temperature acquisition unit 152 outputs the outside-air temperature to the central control unit 157.

Further, the power acquisition unit 151 in the system control unit 150 acquires electronic equipment power consumption (power consumption of the electronic equipment 70 in the rack 60) measured by the power sensor 100 from the power sensor 100. Then, the power acquisition unit 151 outputs the electronic equipment power consumption to the central control unit 157.

When a plurality of outside-air temperature sensors 50 are provided, a maximum value of the temperature values measured by the respective plurality of outside-air temperature sensors 50 is set as the outside-air temperature. Further, when a plurality of outside-air temperature sensors 50 are provided, a minimum value or a mean value of the temperature values measured by the respective plurality of outside-air temperature sensors 50 may be set as the outside-air temperature.

Next, the system control unit 150 performs predetermined control (S2). Specifically, the central control unit 157 in the system control unit 150 refers to the data table 156. That is to say, the central control unit 157 extracts motive power (e.g. a revolving speed) of the blowing unit 40, a degree of opening of the rack louver 120, and a degree of opening of the outlet louver 130 that are prestored in the data table 156, in accordance with an outside-air temperature acquired by the temperature acquisition unit 152 and electronic equipment power consumption acquired by the power acquisition unit 151.

Then, the central control unit 157 outputs the respective pieces of data extracted from the data table 156 to the blowing control unit 153, the rack louver control unit 154, and the outlet louver control unit 155. Specifically, the central control unit 157 outputs the motive power (e.g. a revolving speed) of the blowing unit 40 extracted from the data table 156 to the blowing control unit 153. Further, the central control unit 157 outputs the degree of opening of the rack louver 120 extracted from the data table 156 to the rack louver control unit 154. Further, the central control unit 157 outputs the degree of opening of the outlet louver 130 extracted from the data table 156 to the outlet louver control unit 155.

Next, the system control unit 150 controls motive power (e.g. a revolving speed) of the blowing unit 40 (S3), controls a degree of opening of the rack louver 120 (S4), and controls a degree of opening of the outlet louver (S5).

Specifically, the blowing control unit 153 adjusts motive power (e.g. a revolving speed) of the blowing unit 40 to the value of the motive power (e.g. a revolving speed) of the blowing unit 40 extracted from the data table 156 (S3). The rack louver control unit 154 adjusts a degree of opening of the rack louver 120 to the degree of opening of the rack louver 120 extracted from the data table 156 (S4). The outlet louver control unit 155 adjusts a degree of opening of the outlet louver 130 to the degree of opening of the outlet louver 130 extracted from the data table 156. As described above, the data table 156 stores motive power (e.g. a revolving speed) of the blowing unit 40, a degree of opening of the rack louver 120, and a degree of opening of the outlet louver 130 that are calculated, in relation to an outside-air temperature measured by the outside-air temperature sensor 50 and electronic equipment power consumption measured by the power sensor 100, so as to minimize power usage effectiveness (PUE′) expressed by equation (1). Accordingly, power usage effectiveness (PUE′) can be minimized. Consequently, the electronic equipment 70 in the rack 60 can be cooled with higher energy efficiency while suppressing temperature rise in the electronic equipment 70.

Next, the cooling device 1000 waits for an elapse of a certain time (S6), and then performs the processing in S1 again. As described above, the cooling device 1000 repeats the processing in S1 to S6.

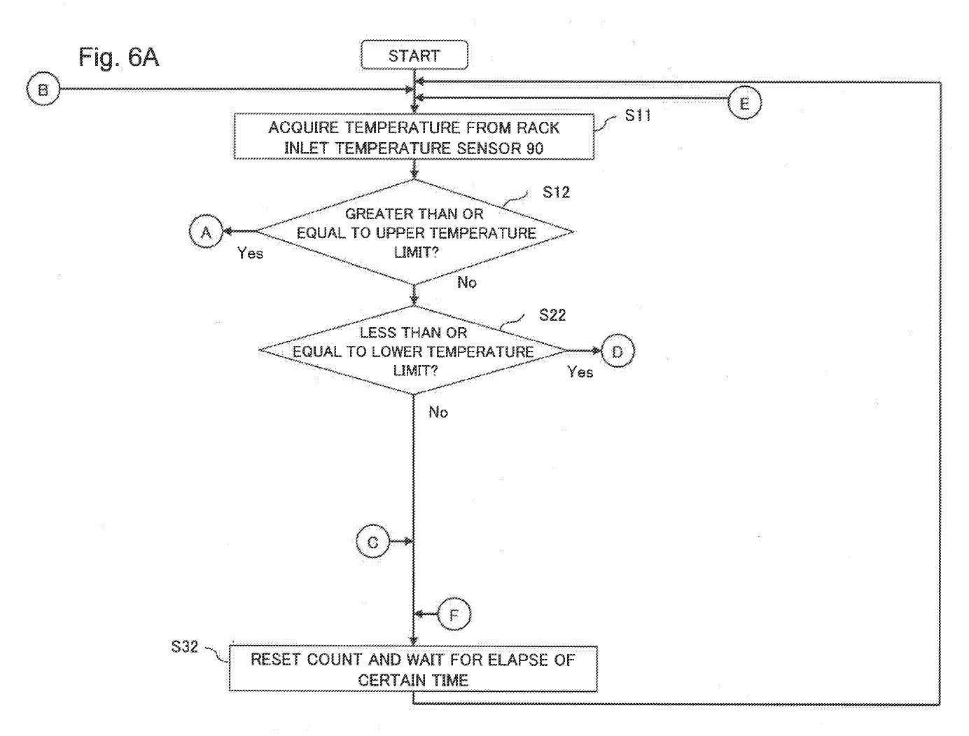

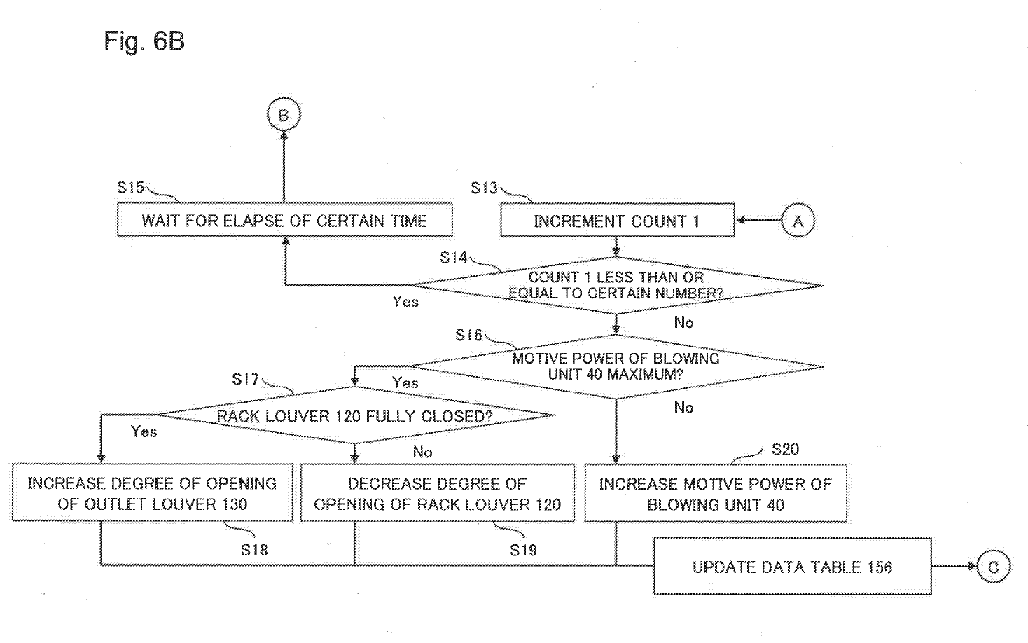

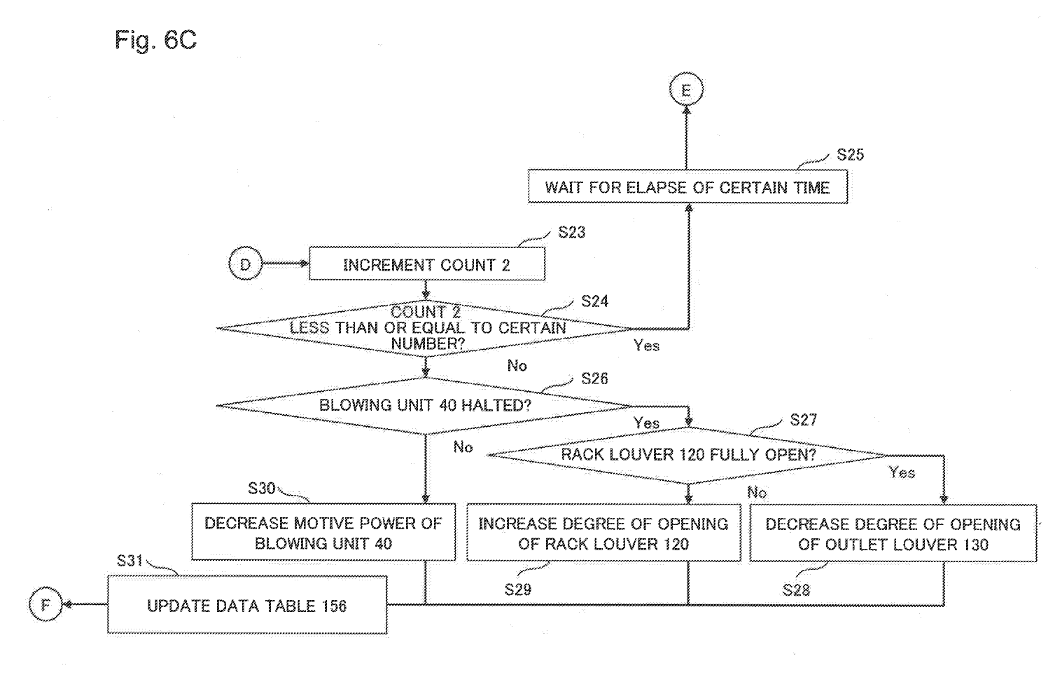

Next, a method of controlling a warm-air circulation amount in the cooling device 1000 will be described. FIGS. 6A to 6C are operational flowcharts for controlling a warm-air circulation amount in the cooling device 1000.

As described above, the data table 156 stores motive power (e.g. a revolving speed) of the blowing unit 40, a degree of opening of the rack louver 120, and a degree of opening of the outlet louver 130 that are calculated, in relation to an outside-air temperature measured by the outside-air temperature sensor 50 and electronic equipment power consumption measured by the power sensor 100, so as to minimize power usage effectiveness (PUE′) expressed by equation (1). Respective numerical values obtained in preparation of the data table 156 are optimally determined so as to minimize cooling power consumption while maintaining a guaranteed intake air temperature range of the electronic equipment 70. Accordingly, by the cooling device 1000 performing the operational flow in FIG. 5, motive power (e.g. a revolving speed) of the blowing unit 40, a degree of opening of the rack louver 120, and a degree of opening of the outlet louver are adjusted so that an intake air temperature of the electronic equipment 70 is kept within the guaranteed operating temperature range of the electronic equipment 70.

However, when some environmental change occurs in the enclosure 10, it is considered that an intake air temperature of the electronic equipment 70 goes out of the guaranteed operating temperature range of the electronic equipment 70. As a countermeasure, the cooling device 1000 performs the operational flow illustrated in FIGS. 6A to C in parallel with the operational flow in FIG. 5.

As indicated in FIG. 6A, the system control unit 150 first acquires a temperature near the inlet on the rack 60 from the rack inlet temperature sensor 90 (S11).

The system control unit 150 determines whether or not the temperature near the inlet on the rack 60 is greater than or equal to an upper temperature limit (e.g. 40° C.) (S12).

When a plurality of rack inlet temperature sensors 90 are provided, a maximum value of the temperature values measured by the respective plurality of rack inlet temperature sensors 90 is set as the temperature near the inlet of the rack 60. Further, when a plurality of rack inlet temperature sensors 90 are provided, a minimum value or a mean value of the temperature values measured by the plurality of rack inlet temperature sensors 90 may be set as the temperature near the inlet on the rack 60.

When the system control unit 150 determines that the temperature near the inlet on the rack 60 is greater than or equal to the upper temperature limit (e.g. 40° C.) (S12, Yes), the system control unit 150 performs processing in S13.

On the other hand, when the system control unit 150 determines that the temperature near the inlet on the rack 60 is not greater than or equal to the upper temperature limit (e.g. 40° C.) (S12, No), the system control unit 150 performs processing in S22.

In the processing in S13, the system control unit 150 increments a count 1 by one (S13). The count 1 is a number counted by a counter being a machine for counting. Next, the system control unit 150 determines whether or not the count 1 is less than or equal to a certain number (S14).

When the system control unit 150 determines that the count 1 is less than or equal to the certain number (S14, Yes), the system control unit 150 waits for an elapse of a certain time (S15), and then returns to the processing in S11.

On the other hand, when the system control unit 150 determines that the count 1 is not less than or equal to the certain number, (S14, No), the system control unit 150 determines whether or not motive power (e.g. a revolving speed) of the blowing unit 40 is maximum (S16).

When the system control unit 150 determines that the motive power (e.g. a revolving speed) of the blowing unit 40 is maximum (S16, Yes), the system control unit 150 determines whether or not a degree of opening of the rack louver 120 is fully closed (S17).

On the other hand, when the system control unit 150 determines that the motive power (e.g. a revolving speed) of the blowing unit 40 is not maximum (S16, No), the system control unit 150 outputs an instruction to increase the motive power (e.g. a revolving speed) of the blowing unit 40 to the blowing unit 40 (S20). Then the blowing unit 40 operates with increased motive power.

When the system control unit 150 determines in S17 that the degree of opening of the rack louver 120 is fully closed (S17, Yes), the system control unit 150 outputs an instruction to increase a degree of opening of the outlet louver 130 to the outlet louver 130 (S18). Then, the outlet louver 130 operates with an increased degree of opening.

On the other hand, when the system control unit 150 determines in S17 that the degree of opening of the rack louver 120 is not fully closed (S17, No), the system control unit 150 outputs an instruction to decrease the degree of opening of the rack louver 120 to the rack louver 120 (S19). Then the rack louver 120 operates with a decreased degree of opening.

After the processing in S18, S19 or S20, the system control unit 150 updates the data table 156 (S21). Specifically, the system control unit 150 rewrites a degree of opening of the outlet louver 130 stored in the data table 156 to the degree of opening of the outlet louver 130 changed in the processing in S18. Further, the system control unit 150 rewrites a degree of opening of the rack louver 120 stored in the data table 156 to the degree of opening of the rack louver 120 changed in the processing in S19. Further, the system control unit 150 rewrites motive power (e.g. a revolving speed) of the blowing unit 40 stored in the data table 156 to the motive power of the blowing unit 40 changed in the processing in S20.

Next, the system control unit 150 resets the count, waits for an elapse of a certain time (S32), and then performs the processing in S11 again. Then, the system control unit 150 repeats the aforementioned processing.

When transitioning from S12 to S22 (S12, No), the system control unit 150 performs the processing in S22.

In S22, the system control unit 150 determines whether or not a temperature near the inlet on the rack 60 is less than or equal to a lower temperature limit (e.g. 10° C.) (S22).

When the system control unit 150 determines that the temperature near the inlet on the rack 60 is less than or equal to the lower temperature limit (e.g. 10° C.) (S22, Yes), the system control unit 150 performs processing in S23.

On the other hand, when the system control unit 150 determines that the temperature near the inlet on the rack 60 is not less than or equal to the lower temperature limit (e.g. 10° C.) (S22, No), the system control unit 150 performs processing in S32.

In the processing in S23, the system control unit 150 increments a count 2 by one (S23). Similarly to the count 1, the count 2 is a number counted by a counter being a machine for counting. Next, the system control unit 150 determines whether or not the count 2 is less than or equal to a certain number (S24).

When the system control unit 150 determines that the count 2 is less than or equal to the certain number (S24, Yes), the system control unit 150 waits for an elapse of a certain time (S25), and then returns to the processing in S11.

On the other hand, when the system control unit 150 determines that the count 2 is not less than or equal to the certain number, (S24, No), the system control unit 150 determines whether or not the blowing unit 40 is halted (S26).

When the system control unit 150 determines that the blowing unit 40 is halted (S26, Yes), the system control unit 150 determines whether or not the degree of opening of the rack louver 120 is fully open (S27).

On the other hand, when the system control unit 150 determines that the blowing unit 40 is not halted (S26, No), the system control unit 150 outputs an instruction to decrease the motive power (e.g. a revolving speed) of the blowing unit 40 to the blowing unit 40 (S30). Then, the blowing unit 40 operates with decreased motive power.

When the system control unit 150 determines in S27 that the degree of opening of the rack louver 120 is fully open (S27, Yes), the system control unit 150 outputs an instruction to decrease the degree of opening of the outlet louver 130 to the outlet louver 130 (S28). Then, the outlet louver 130 operates with a decreased degree of opening.

On the other hand, when the system control unit 150 determines in S27 that the degree of opening of the rack louver 120 is not fully open (S27, No), the system control unit 150 outputs an instruction to increase the degree of opening of the rack louver 120 to the rack louver 120 (S29). Then, the rack louver 120 operates with an increased degree of opening.

After the processing in S28, S29, or S30, the system control unit 150 updates the data table 156 (S31). Specifically, the system control unit 150 rewrites a degree of opening of the outlet louver 130 stored in the data table 156 to the degree of opening of the outlet louver 130 changed in the processing in S28. Further, the system control unit 150 rewrites a degree of opening of the rack louver 120 stored in the data table 156 to the degree of opening of the rack louver 120 changed in the processing in S29. Further, the system control unit 150 rewrites motive power (e.g. a revolving speed) of the blowing unit 40 stored in the data table 156 to motive power of the blowing unit 40 changed in the processing in S30.

Next, the system control unit 150 resets the count, waits for an elapse of a certain time (S32), and performs the processing in S11 again. Then, the system control unit 150 repeats the aforementioned processing.

The operation of the cooling device 1000 has been described above.

As described above, the cooling device 1000 according to the first exemplary embodiment of the present invention includes the enclosure 10, the inlet 20, the outlet 30, the blowing unit 40, the outside-air temperature sensor 50, the rack 60, the electronic equipment fan 80, the power sensor 100, the rack louver 120, the outlet louver 130, and the system control unit 150.

The inlet 20 is provided on the enclosure 10 and is intended to take outside air external to the enclosure 10 into the enclosure 10. The outlet 30 is provided on the enclosure 10 and is intended to discharge inside air internal to the enclosure 10 to outside the enclosure 10. The blowing unit 40 is provided in the enclosure 10, takes outside air external to the enclosure 10 into the enclosure 10 through the inlet 20, and also discharges inside air internal to the enclosure 10 to outside the enclosure 10 through the outlet 30.

The outside-air temperature sensor 50 measures a temperature of outside air external to the enclosure 10 as an outside-air temperature.

The rack 60 is provided between the inlet 20 and the outlet 30 in the enclosure 10 and houses the electronic equipment 70. The electronic equipment fan 80 is provided in the electronic equipment 70, takes outside air external to the rack 60 into the rack 60, and also discharges inside air internal to the rack 60 to outside the rack 60. The power sensor 100 measures power consumption of the electronic equipment 70 in the rack 60 as electronic equipment power consumption.

The rack louver 120 is provided between the inlet and the outlet in the enclosure and on an upper side of the rack 60 in the enclosure 10 so as to separate air taken into the rack 60 and air discharged from the rack 60. The rack louver 120 controls an air flow of outside air external to the enclosure 10 taken into the rack 10, flowing from the inlet 20 to the outlet 30.

The outlet louver 130 controls an air flow of inside air internal to the enclosure 10 flowing out from the outlet 30 to outside the enclosure 10.

The system control unit 150 adjusts motive power of the blowing unit 40, a degree of opening of the rack louver 120, and a degree of opening of the outlet louver 130 in accordance with an outside-air temperature measured by the outside-air temperature sensor 50 and electronic equipment power consumption measured by the power sensor 100.

Thus, the system control unit 150 comprehensively adjusts motive power of the blowing unit 40, a degree of opening of the rack louver 120, and a degree of opening of the outlet louver 130 in accordance with an outside-air temperature measured by the outside-air temperature sensor 50 and electronic equipment power consumption measured by the power sensor 100.

That is to say, the cooling device 1000 is able to properly change motive power of the blowing unit 40, a degree of opening of the rack louver 120, and a degree of opening of the outlet louver 130 with respect to any values of an outside-air temperature and electronic equipment power consumption while maintaining an intake air temperature of the electronic equipment 70 (e.g. a server) within a guaranteed temperature range. Consequently, power consumption (PUE′) of the cooling equipment including the fan in the electronic equipment 70 can be minimized. Accordingly, the cooling device 1000 is able to cool the electronic equipment 70 in the rack 60 with higher energy efficiency while suppressing temperature rise in the electronic equipment 70.

Further, the cooling device 1000 according to the first exemplary embodiment of the present invention includes the data table 156.

The data table 156 stores motive power (e.g. a revolving speed) of the blowing unit 40, a degree of opening of the rack louver 120, and a degree of opening of the outlet louver 130 that are calculated, in relation to an outside-air temperature measured by the outside-air temperature sensor 50 and electronic equipment power consumption measured by the power sensor 100, so as to minimize power usage effectiveness (PUE′) expressed by aforementioned equation (1).

Then, the system control unit 150 adjusts motive power of the blowing unit 40, a degree of opening of the rack louver 120, and a degree of opening of the outlet louver 130 to motive power of the blowing unit 40, a degree of opening of the rack louver 120, and a degree of opening of the outlet louver 130 that are stored in the data table 156, in accordance with an outside-air temperature measured by the outside-air temperature sensor 50 and electronic equipment power consumption measured by the power sensor 100.

Thus, the data table 156 stores motive power (e.g. a revolving speed) of the blowing unit 40, a degree of opening of the rack louver 120, and a degree of opening of the outlet louver 130 that are calculated, in relation to an outside-air temperature measured by the outside-air temperature sensor 50 and electronic equipment power consumption measured by the power sensor 100, so as to minimize power usage effectiveness (PUE′). Accordingly, proper numerical values of motive power (e.g. a revolving speed) of the blowing unit 40, a degree of opening of the rack louver 120, and a degree of opening of the outlet louver 130 can be stably retained in the data table 156. Then, the system control unit 150 adjusts motive power of the blowing unit 40 to motive power of the blowing unit 40 stored in the data table 156, in accordance with an outside-air temperature measured by the outside-air temperature sensor 50 and electronic equipment power consumption measured by the power sensor 100. Further, the system control unit 150 adjusts a degree of opening of the rack louver 120 to a degree of opening of the rack louver 120 stored in the data table 156, in accordance with an outside-air temperature measured by the outside-air temperature sensor 50 and electronic equipment power consumption measured by the power sensor 100. Further, the system control unit 150 adjusts a degree of opening of the outlet louver 130 to a degree of opening of the outlet louver 130 stored in the data table 156, in accordance with an outside-air temperature measured by the outside-air temperature sensor 50 and electronic equipment power consumption measured by the power sensor 100. Accordingly, the system control unit 150 is able to more stably adjust motive power of the blowing unit 40, a degree of opening of the rack louver 120, and a degree of opening of the outlet louver 130 to proper numerical values.

Consequently, power consumption (PUE′) of the cooling equipment including the fan in the electronic equipment 70 can always be minimized. Accordingly, the cooling device 1000 is able to cool the electronic equipment 70 in the rack 60 with higher energy efficiency while suppressing temperature rise in the electronic equipment 70.

The cooling device 1000 according to the first exemplary embodiment of the present invention may include a regression line storage unit in place of the data table 156.

The regression line storage unit stores a regression line defining a relation between motive power (e.g. a revolving speed) of the blowing unit 40, a degree of opening of the rack louver 120, and a degree of opening of the outlet louver 130 that are calculated, in relation to an outside-air temperature measured by the outside-air temperature sensor 50 and electronic equipment power consumption measured by the power sensor 100, so as to minimize power usage effectiveness (PUE′) in equation (1). Specifically, at a certain outside-air temperature, by performing multiple regression analysis with motive power of the blowing unit 40, degree of opening of the rack louver 120, and a degree of opening of the outlet louver 130 as explanatory variables and PUE′ as a response variable, coefficients of the respective explanatory variables can be acquired, and a regression line can be obtained.

Then, the system control unit 150 adjusts motive power of the blowing unit 40, a degree of opening of the rack louver 120, and a degree of opening of the outlet louver 130 by use of the regression line, in accordance with an outside-air temperature measured by the outside-air temperature sensor 50 and electronic equipment power consumption measured by the power sensor 100.

The configuration also provides an effect similar to the case using the data table 156.

Further, a control program according to the first exemplary embodiment of the present invention is a control program of the cooling device 1000 having a configuration described below. That is to say, the cooling device 1000 includes the enclosure 10, the inlet 20, the outlet 30, the blowing unit 40, the outside-air temperature sensor 50, the rack 60, the electronic equipment fan 80, the power sensor 100, the rack louver 120, and the outlet louver 130.

The inlet 20 is provided on the enclosure 10 and is intended to take outside air external to the enclosure 10 into the enclosure 10. The outlet 30 is provided on the enclosure 10 and is intended to discharge inside air internal to the enclosure 10 to outside the enclosure 10. The blowing unit 40 is provided in the enclosure 10, takes outside air external to the enclosure 10 into the enclosure 10 through the inlet 20, and also discharges inside air internal to the enclosure 10 to outside the enclosure 10 through the outlet 30.

The outside-air temperature sensor 50 measures a temperature of outside air external to the enclosure 10 as an outside-air temperature.

The rack 60 is provided between the inlet 20 and the outlet 30 in the enclosure 10 and houses the electronic equipment 70. The electronic equipment fan 80 is provided in the rack 60, takes outside air external to the rack 60 into the rack 60, and also discharges inside air internal to the rack 60 to outside the rack 60.

The power sensor 100 measures power consumption of the electronic equipment 70 in the rack 60 as electronic equipment power consumption.

The rack louver 120 is provided in an openable and closable manner between the inlet and the outlet in the enclosure and on an upper side, in the vertical direction, of the rack 60 in the enclosure 10 so as to separate air taken into the rack 60 and air discharged from the rack 60. By adjusting a degree of opening, the rack louver 120 controls an air flow of outside air external to the enclosure 10 taken into the rack 10, flowing from the inlet 20 to the outlet 30 on the upper side, in the vertical direction, of the rack 60.

The outlet louver 130 is provided in an openable and closable manner on the outlet 30. By adjusting a degree of opening, the outlet louver 130 controls an air flow of inside air internal to the enclosure 10 flowing out from the outlet 30 to outside the enclosure 10.

Then, the control program causes a computer to perform control of adjusting motive power of the blowing unit 40, a degree of opening of the rack louver 120, and a degree of opening of the outlet louver 130 in accordance with an outside-air temperature measured by the outside-air temperature sensor 50 and electronic equipment power consumption measured by the power sensor 100.

The configuration also provides an effect similar to the aforementioned cooling device 1000.

### Second Exemplary Embodiment

A configuration of a cooling device 1000A according to a second exemplary embodiment of the present invention will be described.

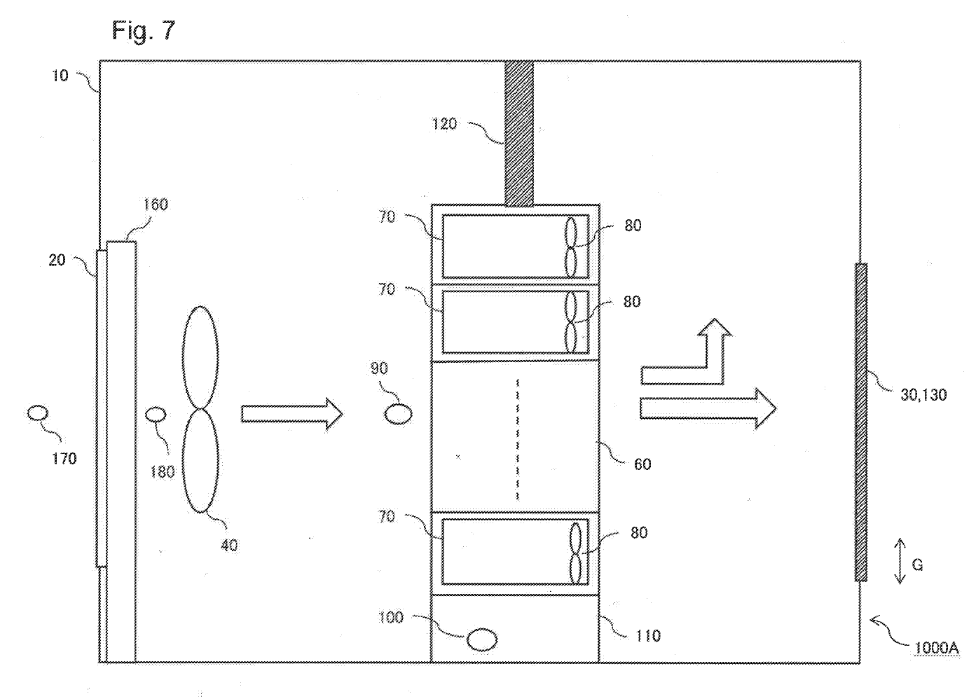

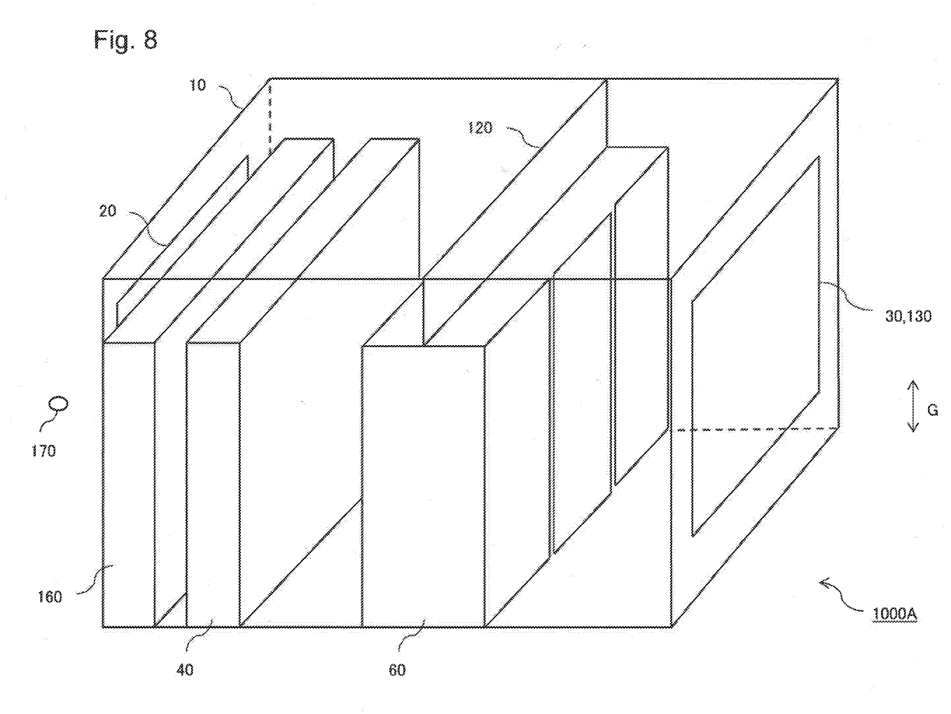

FIG. 7 is a cross-sectional view illustrating the configuration of the cooling device 1000A. FIG. 8 is a transparent perspective view transparently illustrating the configuration of the cooling device 1000A. A vertical direction G is illustrated in FIGS. 7 and 8. In FIGS. 7 and 8, a component equivalent to each component illustrated in FIGS. 1 to 6 is given a reference sign equivalent to the reference sign given in FIGS. 1 to 6.

As illustrated in FIGS. 7 and 8, the cooling device 1000A includes an enclosure 10, an inlet 20, an outlet 30, a blowing unit 40, a rack 60, an electronic equipment 70, an electronic equipment fan 80, a rack inlet temperature sensor 90, a power sensor 100, an electronic equipment accessory 110, a rack louver 120, an outlet louver 130, a vaporizing-type cooling unit 160, an outside-air temperature-humidity sensor 170, and an inside-air temperature-humidity sensor 180. The cooling device 1000A is also called a module-type data center.

FIGS. 1 and 2, and FIGS. 7 and 8 will be compared. FIGS. 7 and 8 differ from FIGS. 1 and 2 in that the vaporizing-type cooling unit 160 and the inside-air temperature-humidity sensor 180 are newly provided. Further, in FIG. 7, the outside-air temperature-humidity sensor 170 is provided in place of the outside-air temperature sensor 50 in FIG. 1. The two differ from one another in this respect as well.

As illustrated in FIGS. 7 and 8, the vaporizing-type cooling unit 160 is provided in the enclosure 10 so as to face the inlet 20. By use of vapor, the vaporizing-type cooling unit 160 raises humidity in the enclosure 10 and lowers a temperature in the enclosure 10. For example, the vaporizing-type cooling unit 160 is composed of mist cooling equipment and the like.

As illustrated in FIGS. 7 and 8, the outside-air temperature-humidity sensor 170 is provided outside the enclosure 10 and near the inlet 20. The outside-air temperature-humidity sensor 170 measures a temperature of outside air external to the enclosure 10 as an outside-air temperature and also measures humidity of outside air external to the enclosure 10 as outside-air humidity. The outside-air temperature-humidity sensor 170 may be configured with two pieces of equipment: an outside-air temperature sensor 50 and an outside-air humidity sensor. In this case, the outside-air temperature sensor 50 measures a temperature of outside air external to the enclosure 10 as an outside-air temperature. The outside-air humidity sensor measures humidity of outside air external to the enclosure 10 as outside-air humidity.

As illustrated in FIG. 7, the inside-air temperature-humidity sensor 180 is provided between the vaporizing-type cooling unit 160 and the blowing unit 40 in the enclosure 10. The inside-air temperature-humidity sensor 180 measures a temperature of inside air internal to the enclosure 10 as an inside-air temperature and also measures humidity of inside air internal to the enclosure 10 as an inside-air humidity. The inside-air temperature-humidity sensor 180 may be configured with two pieces of equipment: an inside-air temperature sensor and an inside-air humidity sensor. In this case, the inside-air temperature sensor measures a temperature of inside air internal to the enclosure 10 as an inside-air temperature. The inside-air humidity sensor measures humidity of inside air internal to the enclosure 10 as inside-air humidity.

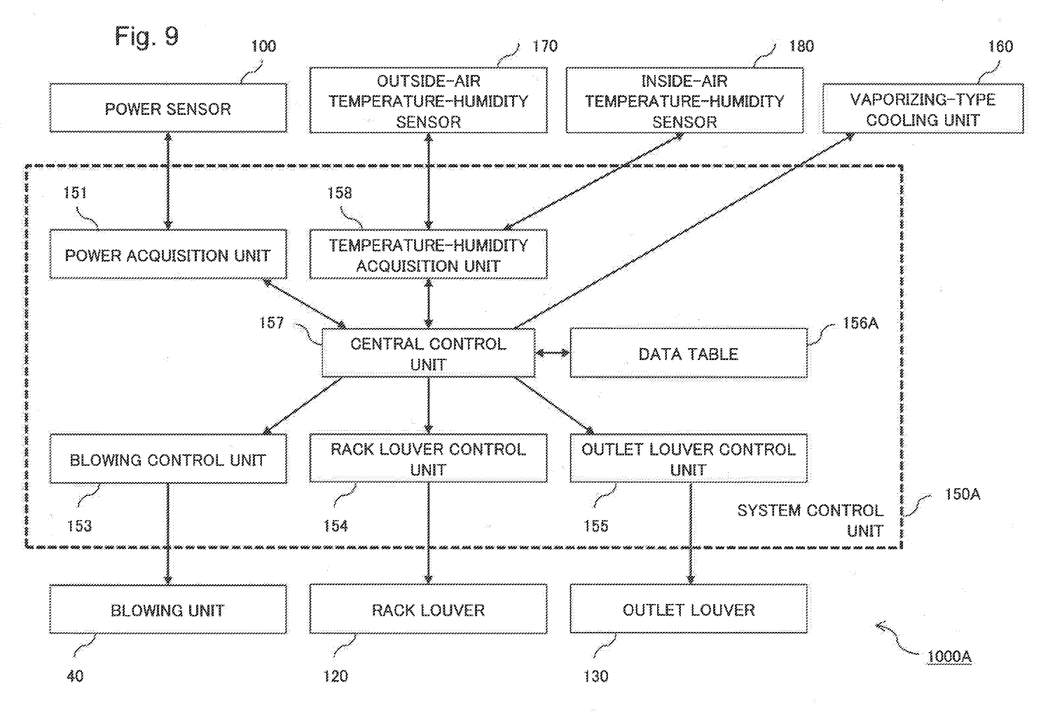

Next, a configuration of an electric circuit in the cooling device 1000A will be described. FIG. 9 is a block diagram illustrating the configuration of the electric circuit in the cooling device 1000A. Further, a direction of an arrow in the drawing represents an example and does not limit a signal direction between blocks.

As illustrated in FIG. 9, the cooling device 1000A includes a system control unit 150A. The system control unit 150A is connected to the power sensor 100, the outside-air temperature-humidity sensor 170, the inside-air temperature-humidity sensor 180, the vaporizing-type cooling unit 160, the blowing unit 40, the rack louver 120, and the outlet louver 130. It is assumed that the system control unit 150A is provided in a local server in the cooling device 1000A. However, the system control unit 150A may be provided on a cloud.

As illustrated in FIG. 9, the system control unit 150A includes a power acquisition unit 151, a temperature-humidity acquisition unit 158, a blowing control unit 153, a rack louver control unit 154, an outlet louver control unit 155, a data table 156A, and a central control unit 157.

The system control unit 150A adjusts motive power of the blowing unit 40 and the like in accordance with an outside-air temperature and outside-air humidity that are measured by the outside-air temperature-humidity sensor 170, or an inside-air temperature and inside-air humidity that are measured by the inside-air temperature-humidity sensor 180, and electronic equipment power consumption measured by the power sensor 100.

Specifically, the system control unit 150A adjusts motive power of the blowing unit 40, a degree of opening of the rack louver 120, and a degree of opening of the outlet louver 130 in accordance with an outside-air temperature and outside-air humidity that are measured by the outside-air temperature-humidity sensor 170, and electronic equipment power consumption measured by the power sensor 100. Alternatively, the system control unit 150A adjusts motive power of the blowing unit 40, a degree of opening of the rack louver 120, and a degree of opening of the outlet louver 130 in accordance with an inside-air temperature and inside-air humidity that are measured by the inside-air temperature-humidity sensor 180, and electronic equipment power consumption measured by the power sensor 100.

The temperature-humidity acquisition unit 158 is connected to the outside-air temperature-humidity sensor 170, the inside-air temperature-humidity sensor 180, and the central control unit 157. The temperature-humidity acquisition unit 158 acquires an outside-air temperature (a temperature of outside air external to the enclosure 10) and outside-air humidity (humidity of outside air external to the enclosure 10) that are measured by the outside-air temperature-humidity sensor 170 from the outside-air temperature-humidity sensor 170. Further, the temperature-humidity acquisition unit 158 outputs an outside-air temperature and outside-air humidity to the central control unit 157. Further, the temperature-humidity acquisition unit 158 acquires an inside-air temperature (a temperature of inside air internal to the enclosure 10) and inside-air humidity (humidity of inside air internal to the enclosure 10) that are measured by the inside-air temperature-humidity sensor 180 from the inside-air temperature-humidity sensor 180. Further, the temperature-humidity acquisition unit 158 outputs an inside-air temperature and inside-air humidity to the central control unit 157.

The data table 156A is connected to the central control unit 157. The data table 156A stores motive power (e.g. a revolving speed) of the blowing unit 40 and the like calculated, in relation to an outside-air temperature and outside-air humidity that are measured by the outside-air temperature-humidity sensor 170, and electronic equipment power consumption measured by the power sensor 100, so as to minimize power usage effectiveness (PUE′) expressed by equation (2) below. Alternatively, the data table 156A stores motive power (e.g. a revolving speed) of the blowing unit 40 and the like calculated, in relation to an inside-air temperature and inside-air humidity that are measured by the inside-air temperature-humidity sensor 180, and electronic equipment power consumption measured by the power sensor 100, so as to minimize power usage effectiveness (PUE′) expressed by equation (2) below. The aforementioned motive power (e.g. a revolving speed) of the blowing unit 40 and the like include a degree of opening of the rack louver 120 and a degree of opening of the outlet louver 130, in addition to motive power (e.g. a revolving speed) of the blowing unit 40.

power usage effectiveness (PUE′)=[(power consumption of the electronic equipment−power consumption of the electronic equipment fan)+(power consumption of the blowing unit+power consumption of the vaporizing-type cooling unit+power consumption of the electronic equipment fan)]/(power consumption of the electronic equipment−power consumption of the electronic equipment fan) equation (2)

A preparation method of the data table 156A employs a method similar to the preparation method of the data base 156.

The central control unit 157 is connected to the power acquisition unit 151, the temperature-humidity acquisition unit 158, the blowing control unit 153, the rack louver control unit 154, the outlet louver control unit 155, and the data table 156A. The central control unit 157 outputs an instruction signal and the like to the power acquisition unit 151, the temperature-humidity acquisition unit 158, the blowing control unit 153, the rack louver control unit 154, the outlet louver control unit 155, and the data table 156A.

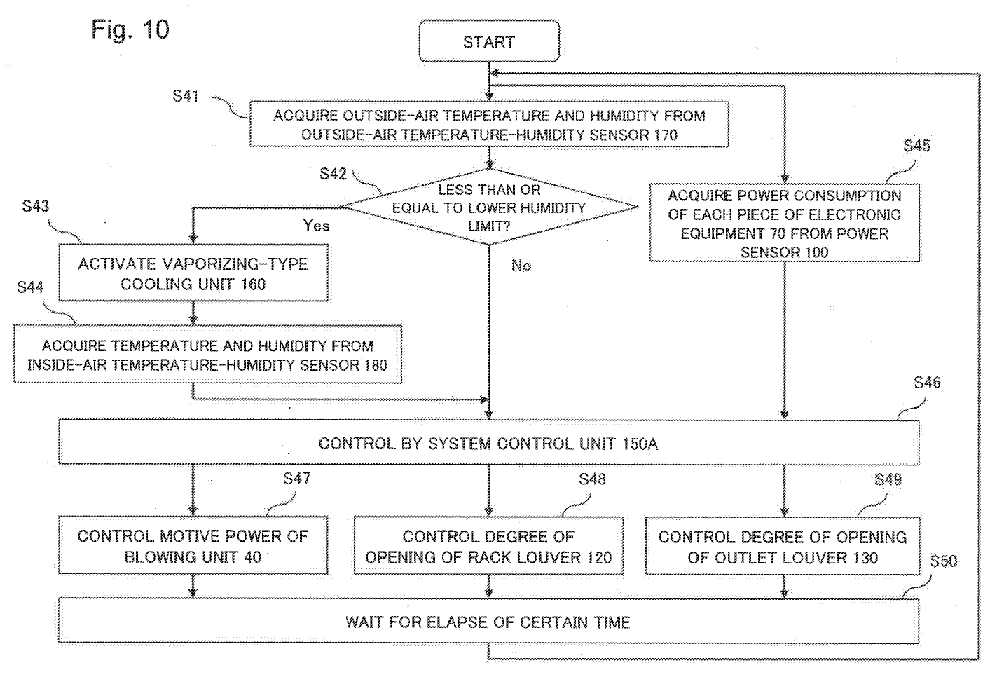

Next, an operation of the cooling device 1000A will be described. FIG. 10 is an operational flowchart of the cooling device 1000A.

As indicated in FIG. 10, first, the system control unit 150A acquires an outside-air temperature and outside-air humidity from the outside-air temperature-humidity sensor 170 (S41).

More specifically, the temperature-humidity acquisition unit 158 in the system control unit 150 acquires an outside-air temperature (a temperature of outside air external to the enclosure 10) and outside-air humidity (humidity of outside air external to the enclosure 10) that are measured by the outside-air temperature-humidity sensor 170 from the outside-air temperature-humidity sensor 170. Then, the temperature-humidity acquisition unit 158 outputs the outside-air temperature and the outside-air humidity to the central control unit 157.

Further, the power acquisition unit 151 in the system control unit 150A acquires electronic equipment power consumption (power consumption of the electronic equipment 70 in the rack 60) measured by the power sensor 100 from the power sensor 100 (S45). Then, the power acquisition unit 151 outputs the electronic equipment power consumption to the central control unit 157.

Next, the central control unit 157 determines whether or not the outside-air humidity acquired by the temperature-humidity acquisition unit 158 is less than or equal to a lower humidity limit (the measured humidity is less than or equal to a preset lower limit such as absolute humidity 10%) (S42).

When a plurality of outside-air temperature-humidity sensors 170 are provided, a minimum value of the humidity values measured by the respective plurality of outside-air temperature-humidity sensors 170 is set as the outside-air humidity. Further, when a plurality of outside-air temperature-humidity sensors 170 are provided, a maximum value or a mean value of the humidity values measured by the respective plurality of outside-air temperature-humidity sensors 170 may be set as the outside-air humidity.

When the central control unit 157 determines that the outside-air humidity acquired by the temperature-humidity acquisition unit 158 is less than or equal to the lower humidity limit (S42, Yes), the system control unit 150A performs processing in S43.

In S43, the central control unit 156 in the system control unit 150A activates the vaporizing-type cooling unit 160 (S43). Consequently, by use of vapor, the vaporizing-type cooling unit 160 raises humidity in the enclosure 10 and lowers a temperature in the enclosure 10.

Subsequently, the system control unit 150A acquires an inside-air temperature and inside-air humidity from the inside-air temperature-humidity sensor 180 (S44).

More specifically, the temperature-humidity acquisition unit 158 in the system control unit 150A acquires an inside-air temperature (a temperature of inside air internal to the enclosure 10) and inside-air humidity (humidity of inside air internal to the enclosure 10) that are measured by the inside-air temperature-humidity sensor 180 from the inside-air temperature-humidity sensor 180. Then, the temperature-humidity acquisition unit 158 outputs the inside-air temperature and the inside-air humidity to the central control unit 157.

On the other hand, when the central control unit 157 determines that the outside-air humidity acquired by the temperature-humidity acquisition unit 158 is not less than or equal to the lower humidity limit (S42, No), the system control unit 150A performs processing in S46. Additionally, the temperature-humidity acquisition unit 158 outputs the outside-air temperature and the outside-air humidity to the central control unit 157.

Next, the system control unit 150A performs predetermined control (S46). Specifically, the central control unit 157 in the system control unit 150A refers to the data table 156A. That is to say, the system control unit 150A adjusts motive power of the blowing unit 40, a degree of opening of the rack louver 120, and a degree of opening of the outlet louver 130 that are prestored in the data table 156A, in accordance with the outside-air temperature and the outside-air humidity that are acquired in S41, or the inside-air temperature and the inside-air humidity that are acquired in S44, and the electronic equipment power consumption acquired in S45.

More specifically, the central control unit 157 in the system control unit 150A adjusts motive power of the blowing unit 40 and the like prestored in the data table 156A, in accordance with the outside-air temperature and the outside-air humidity that are measured by the outside-air temperature-humidity sensor 170 (acquired in S41), and the electronic equipment power consumption measured by the power sensor 100 (acquired in S45). The aforementioned motive power of the blowing unit 40 and the like include a degree of opening of the rack louver 120 and a degree of opening of the outlet louver 130, in addition to motive power of the blowing unit 40.

Alternatively, the central control unit 157 in the system control unit 150A adjusts motive power of the blowing unit 40, a degree of opening of the rack louver 120, and a degree of opening of the outlet louver 130 that are prestored in the data table 156A, in accordance with the inside-air temperature and the inside-air humidity that are measured by the inside-air temperature-humidity sensor 180 (acquired in S44), and the electronic equipment power consumption measured by the power sensor 100 (acquired in S45).

Then, the central control unit 157 outputs the respective pieces of data extracted from the data table 156A to the blowing control unit 153, the rack louver control unit 154, and the outlet louver control unit 155. Specifically, the central control unit 157 outputs the motive power (e.g. a revolving speed) of the blowing unit 40 extracted from the data table 156A to the blowing control unit 153. Further, the central control unit 157 outputs the degree of opening of the rack louver 120 extracted from the data table 156A to the rack louver control unit 154. Further, the central control unit 157 outputs the degree of opening of the outlet louver 130 extracted from the data table 156A to the outlet louver control unit 155.

Next, the system control unit 150A controls motive power (e.g. a revolving speed) of the blowing unit 40 (S47), controls a degree of opening of the rack louver 120 (S48), and controls a degree of opening of the outlet louver (S49).

Specifically, the blowing control unit 153 adjusts motive power (e.g. a revolving speed) of the blowing unit 40 to the value of the motive power (e.g. a revolving speed) of the blowing unit 40 extracted from the data table 156A (S47). The rack louver control unit 154 adjusts a degree of opening of the rack louver 120 to the degree of opening of the rack louver 120 extracted from the data table 156A (S48). The outlet louver control unit 155 adjusts a degree of opening of the outlet louver 130 to the degree of opening of the outlet louver 130 extracted from the data table 156A (S49). Thus, power usage effectiveness (PUE′) can be minimized. Consequently, the electronic equipment 70 in the rack 60 can be cooled with higher energy efficiency while suppressing temperature rise in the electronic equipment 70.

Next, the cooling device 1000A waits for an elapse of a certain time (S50) and performs the processing in S41 to S45 again. As described above, the cooling device 1000A repeats the processing in S41 to S50.

The operation of the cooling device 1000A has been described above.

As described above, the cooling device 1000A according to the second exemplary embodiment of the present invention further includes the outside-air humidity sensor, the inside-air temperature sensor, the inside-air humidity sensor, and the vaporizing-type cooling unit 160. The outside-air temperature sensor and the outside-air humidity sensor are included in the outside-air temperature-humidity sensor 170. The inside-air temperature sensor and the inside-air humidity sensor are included in the inside-air temperature-humidity sensor 180. The outside-air humidity sensor (outside-air temperature-humidity sensor 170) measures humidity of outside air external to the enclosure 10 as outside-air humidity. The inside-air temperature sensor (inside-air temperature-humidity sensor 180) measures a temperature of inside air internal to the enclosure 10 as an inside-air temperature. The inside-air humidity sensor (inside-air temperature-humidity sensor 180) measures humidity of inside air internal to the enclosure 10 as inside-air humidity.

When outside-air humidity measured by the outside-air humidity sensor is less than or equal to predetermined humidity, the vaporizing-type cooling unit 160, by use of vapor, raises humidity in the enclosure 10 and lowers a temperature in the enclosure 10.

Then, the system control unit 150A adjusts motive power (e.g. a revolving speed) of the blowing unit 40 and the like in accordance with an outside-air temperature and outside-air humidity that are measured by the outside-air temperature sensor and the outside-air humidity sensor, or an inside-air temperature and inside-air humidity that are measured by the inside-air temperature sensor and the inside-air humidity sensor, and electronic equipment power consumption measured by the power sensor 100.

Specifically, the system control unit 150A adjusts motive power of the blowing unit 40, a degree of opening of the rack louver 120, and a degree of opening of the outlet louver 130 in accordance with an outside-air temperature and outside-air humidity that are measured by the outside-air temperature sensor and the outside-air humidity sensor, and electronic equipment power consumption measured by the power sensor 100. Alternatively, the system control unit 150A adjusts motive power (e.g. a revolving speed) of the blowing unit 40, a degree of opening of the rack louver 120, and a degree of opening of the outlet louver 130 in accordance with an inside-air temperature and inside-air humidity that are measured by the inside-air temperature sensor and the inside-air humidity sensor, and electronic equipment power consumption measured by the power sensor 100.

Such a configuration is also able to provide an effect similar to the effect described in the first exemplary embodiment. Further, by providing the vaporizing-type cooling unit 160, frequency of malfunction and an electrostatic breakdown of the electronic equipment 70 under low outside-air relative humidity such as the winter season in Japan can be reduced. The cooling device 1000A comprehensively adjusts motive power (e.g. a revolving speed) of the blowing unit 40, a degree of opening of the rack louver 120, and a degree of opening of the outlet louver 130, taking into account outside-air humidity, an inside-air temperature, and inside-air humidity, in addition to electronic equipment power consumption and an outside-air temperature.

That is to say, the cooling device 1000A is able to properly change motive power of the blowing unit 40, a degree of opening of the rack louver 120, and a degree of opening of the outlet louver 130 with respect to any values of an outside-air temperature, outside-air humidity, an inside-air temperature, inside-air humidity, and electronic equipment power consumption while maintaining an intake air temperature of the electronic equipment 70 (e.g. a server) within a guaranteed temperature range. Consequently, power consumption (PUE′) of the cooling equipment including the fan in the electronic equipment 70 can be minimized. Accordingly the cooling device 1000A is able to cool the electronic equipment 70 in the rack 60 with higher energy efficiency while suppressing temperature rise in the electronic equipment 70.

Further, the cooling device 1000A according to the second exemplary embodiment of the present invention includes the data table 156A.

The data table 156A stores motive power (e.g. a revolving speed) of the blowing unit 40 and the like calculated, in relation to an outside-air temperature and outside-air humidity that are measured by the outside-air temperature sensor and the outside-air humidity sensor, or an inside-air temperature and inside-air humidity that are measured by the inside-air temperature sensor and the inside-air humidity sensor, and the electronic equipment power consumption measured by the power sensor 100, so as to minimize power usage effectiveness (PUE′) expressed by aforementioned equation (2).

Specifically, the data table 156A stores motive power (e.g. a revolving speed) of the blowing unit 40, a degree of opening of the rack louver 120, and a degree of opening of the outlet louver 130 that are calculated, in relation to an outside-air temperature and outside-air humidity that are measured by the outside-air temperature sensor and the outside-air humidity sensor, and the electronic equipment power consumption measured by the power sensor 100, so as to minimize power usage effectiveness (PUE′) expressed by aforementioned equation (2). Alternatively, the data table 156A stores motive power (e.g. a revolving speed) of the blowing unit 40, a degree of opening of the rack louver 120, and a degree of opening of the outlet louver 130 that are calculated, in relation to an inside-air temperature and inside-air humidity that are measured by the inside-air temperature sensor and the inside-air humidity sensor, and the electronic equipment power consumption measured by the power sensor 100, so as to minimize power usage effectiveness (PUE′) expressed by aforementioned equation (2).

Then, the system control unit 150A adjusts motive power (e.g. a revolving speed) of the blowing unit 40 and the like to motive power of the blowing unit 40 and the like stored in the data table 156A, in accordance with an outside-air temperature and outside-air humidity, or an inside-air temperature and inside-air humidity, and electronic equipment power consumption.

Specifically, the system control unit 150A adjusts motive power (e.g. a revolving speed) of the blowing unit 40 and the like to motive power of the blowing unit 40 and the like stored in the data table 156A, in accordance with an outside-air temperature and outside-air humidity, and electronic equipment power consumption. Alternatively, the system control unit 150A adjusts motive power (e.g. a revolving speed) of the blowing unit 40 and the like to motive power of the blowing unit 40 and the like stored in the data table 156A, in accordance with an inside-air temperature and inside-air humidity, and electronic equipment power consumption. The aforementioned motive power of the blowing unit 40 and the like represent motive power of the blowing unit 40, a degree of opening of the rack louver 120, and a degree of opening of the outlet louver 130.

Consequently, power consumption (PUE′) of the cooling equipment including the fan in the electronic equipment 70 can always be minimized. Accordingly, the cooling device 1000A is able to cool the electronic equipment 70 in the rack 60 with higher energy efficiency while suppressing temperature rise in the electronic equipment 70.

The cooling device 1000A according to the second exemplary embodiment of the present invention may include a regression line storage unit in place of the data table 156A.

The regression line storage unit stores a regression line defining a relation between motive power (e.g. a revolving speed) of the blowing unit 40, a degree of opening of the rack louver 120, and a degree of opening of the outlet louver 130 that are calculated, in relation to an outside-air temperature and outside-air humidity, or an inside-air temperature and inside-air humidity, and electronic equipment power consumption, so as to minimize power usage effectiveness (PUE′) expressed by aforementioned equation (2). Specifically, at a certain temperature and certain humidity, by performing multiple regression analysis with motive power of the blowing unit 40, a degree of opening of the rack louver 120, and a degree of opening of the outlet louver 130 as explanatory variables and PUE′ as a response variable, coefficients of the respective explanatory variables can be acquired, and a regression line can be obtained.
An outside-air temperature and outside-air humidity are measured by the outside-air temperature sensor and the outside-air humidity sensor. An inside-air temperature and inside-air humidity are measured by the inside-air temperature sensor and the inside-air humidity sensor.

Specifically, the regression line storage unit stores a regression line defining a relation between motive power (e.g. a revolving speed) of the blowing unit 40, a degree of opening of the rack louver 120, and a degree of opening of the outlet louver 130 that are calculated, in relation to an outside-air temperature and outside-air humidity, and electronic equipment power consumption, so as to minimize power usage effectiveness (PUE′) expressed by aforementioned equation (2). Alternatively, the regression line storage unit stores a regression line defining a relation between motive power (e.g. a revolving speed) of the blowing unit 40, a degree of opening of the rack louver 120, and a degree of opening of the outlet louver 130 that are calculated, in relation to an inside-air temperature and inside-air humidity, and electronic equipment power consumption, so as to minimize power usage effectiveness (PUE′) expressed by aforementioned equation (2).

Then, the system control unit 150A adjusts motive power (e.g. a revolving speed) of the blowing unit 40, a degree of opening of the rack louver 120, and a degree of opening of the outlet louver 130 by use of the regression line stored in the regression line storage unit, in accordance with an outside-air temperature and outside-air humidity, or an inside-air temperature and inside-air humidity, and electronic equipment power consumption measured by the power sensor 100.

Specifically, the system control unit 150A adjusts motive power (e.g. a revolving speed) of the blowing unit 40, a degree of opening of the rack louver 120, and a degree of opening of the outlet louver 130 by use of the regression line stored in the regression line storage unit, in accordance with an outside-air temperature and outside-air humidity, and electronic equipment power consumption. Alternatively, the system control unit 150A adjusts motive power (e.g. a revolving speed) of the blowing unit 40, a degree of opening of the rack louver 120, and a degree of opening of the outlet louver 130 by use of the regression line stored in the regression line storage unit, in accordance with an inside-air temperature and inside-air humidity, and electronic equipment power consumption.

The configuration also provides an effect similar to the case using the data table 156A.

### Third Exemplary Embodiment

A configuration of a cooling device 1000B according to a third exemplary embodiment of the present invention will be described.

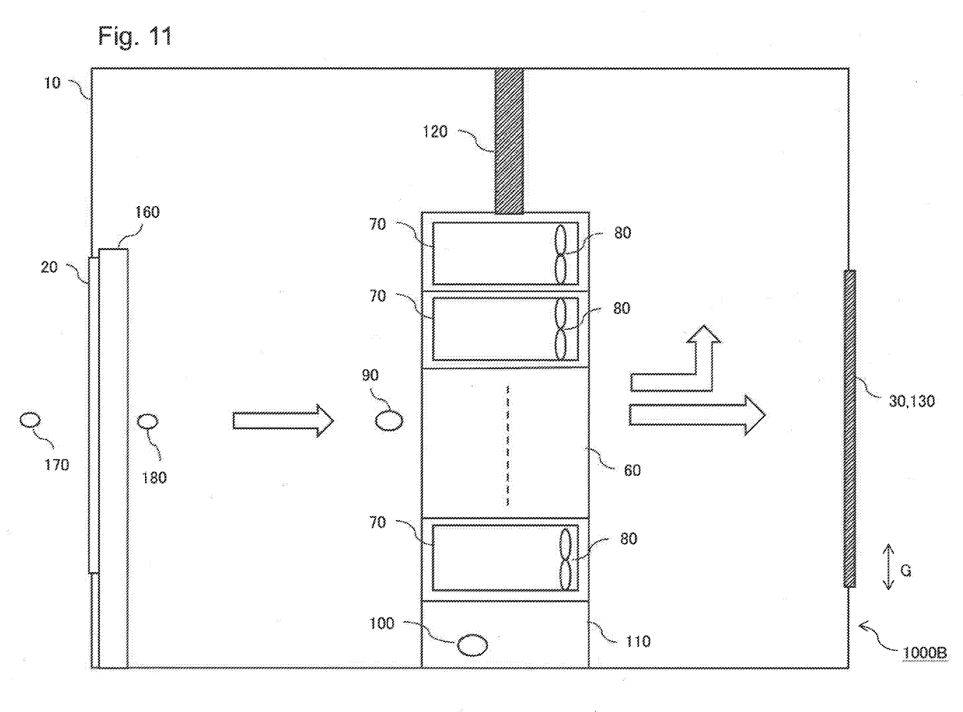

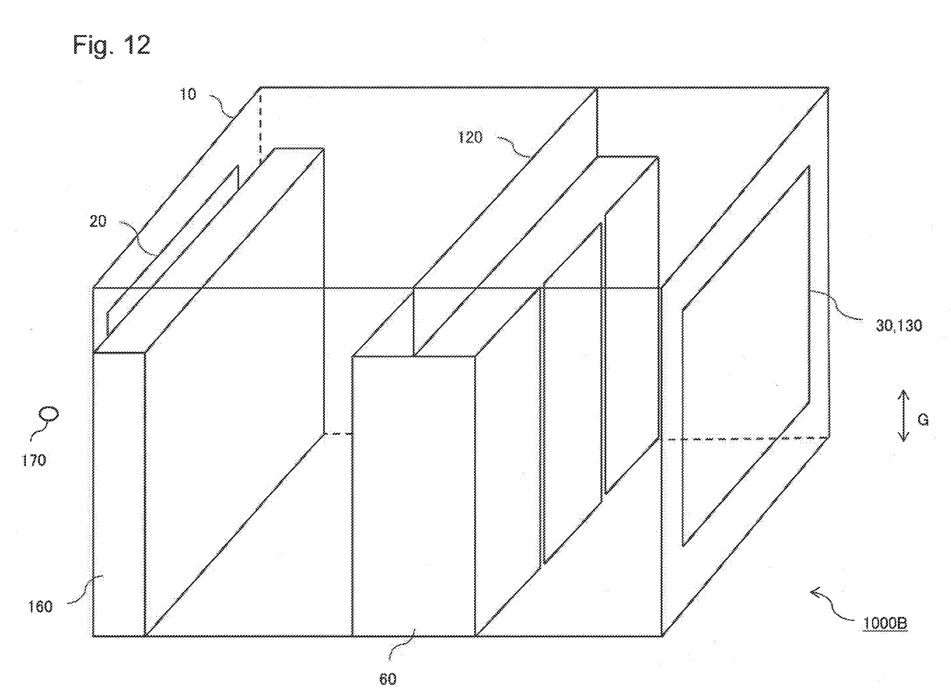

FIG. 11 is a cross-sectional view illustrating the configuration of the cooling device 1000B. FIG. 12 is a transparent perspective view transparently illustrating the configuration of the cooling device 1000B. A vertical direction G is illustrated in FIGS. 11 and 12. In FIGS. 11 and 12, a component equivalent to each component illustrated in FIGS. 1 to 10 is given a reference sign equivalent to the reference sign given in FIGS. 1 to 10.

As illustrated in FIGS. 11 and 12, the cooling device 1000B includes an enclosure 10, an inlet 20, an outlet 30, a rack 60, an electronic equipment 70, an electronic equipment fan 80, a rack inlet temperature sensor 90, a power sensor 100, an electronic equipment accessory 110, a rack louver 120, an outlet louver 130, a vaporizing-type cooling unit 160, an outside-air temperature-humidity sensor 170, and an inside-air temperature-humidity sensor 180. The cooling device 1000B is also called a module-type data center.

FIGS. 7 and 8, and FIGS. 11 and 12 will be compared.

In FIGS. 7 and 8, the blowing unit 40 is provided. By contrast, in FIGS. 11 and 12, the blowing unit 40 is not provided. The two differ from one another in this respect.

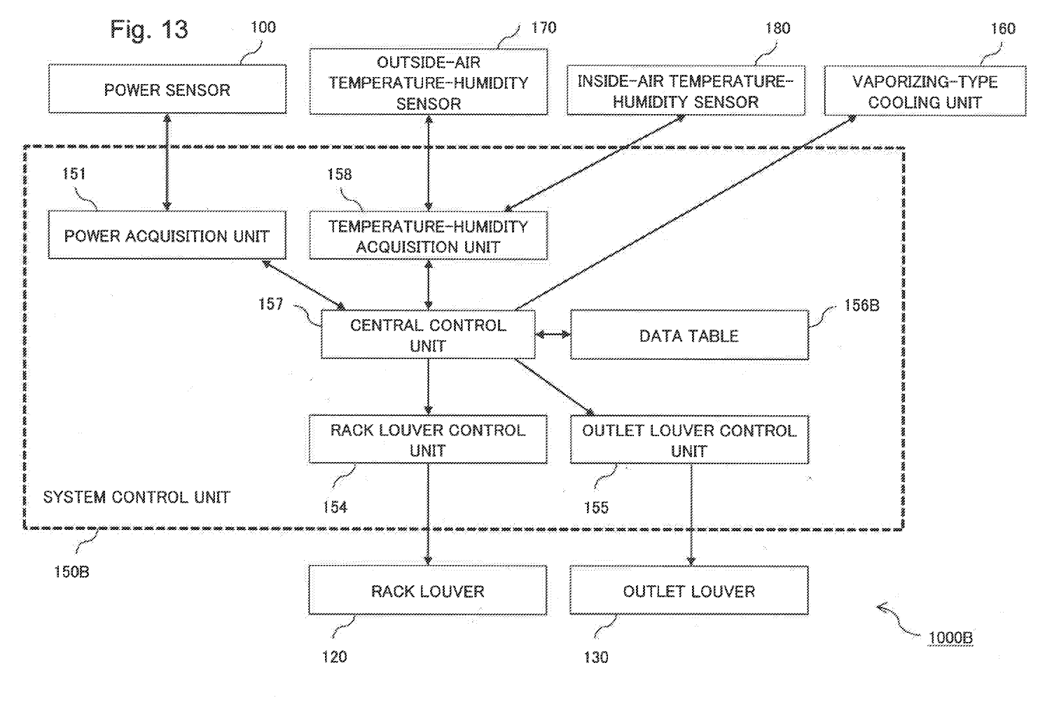

Next, a configuration of an electric circuit in the cooling device 1000B will be described. FIG. 13 is a block diagram illustrating a configuration of an electric circuit in the cooling device 1000B. Further, a direction of an arrow in the drawing represents an example and does not limit a signal direction between blocks.

As illustrated in FIG. 13, the cooling device 1000B includes a system control unit 150B. The system control unit 150B is connected to the power sensor 100, the outside-air temperature-humidity sensor 170, the inside-air temperature-humidity sensor 180, the vaporizing-type cooling unit 160, the rack louver 120, and the outlet louver 130. It is assumed that the system control unit 150B is provided in a local server in the cooling device 1000B. However, the system control unit 150B may be provided on a cloud.

As illustrated in FIG. 13, the system control unit 150B includes a power acquisition unit 151, a temperature-humidity acquisition unit 158, a rack louver control unit 154, an outlet louver control unit 155, a data table 156B, and a central control unit 157.

FIG. 9 and FIG. 13 will be compared. In FIG. 9, the blowing unit 40 and the blowing control unit 153 are provided. By contrast, in FIG. 13, the blowing unit 40 and the blowing control unit 153 are not provided. Further, a data table 156B in FIG. 13 and the data table 156A in FIG. 9 differ from one another. The two differ from one another in these respects.

The system control unit 150B adjusts a degree of opening of the rack louver 120 and a degree of opening of the outlet louver 130 in accordance with an outside-air temperature and outside-air humidity that are measured by the outside-air temperature-humidity sensor 170, or an inside-air temperature and inside-air humidity that are measured by the inside-air temperature-humidity sensor 180, and electronic equipment power consumption measured by the power sensor 100.

Specifically, the system control unit 150B adjusts a degree of opening of the rack louver 120 and a degree of opening of the outlet louver 130 in accordance with an outside-air temperature and outside-air humidity that are measured by the outside-air temperature-humidity sensor 170, and electronic equipment power consumption measured by the power sensor 100. Alternatively, the system control unit 150B adjusts a degree of opening of the rack louver 120 and a degree of opening of the outlet louver 130 in accordance with an inside-air temperature and inside-air humidity that are measured by the inside-air temperature-humidity sensor 180, and electronic equipment power consumption measured by the power sensor 100.

The data table 156B is connected to the central control unit 157. The data table 156B stores a degree of opening of the rack louver 120 and a degree of opening of the outlet louver 130 that are calculated, in relation to an outside-air temperature and outside-air humidity that are measured by the outside-air temperature-humidity sensor 170, and electronic equipment power consumption measured by the power sensor 100, so as to minimize power usage effectiveness (PUE′) expressed by equation (3) below. Alternatively, the data table 156B stores a degree of opening of the rack louver 120 and a degree of opening of the outlet louver 130 that are calculated, in relation to an inside-air temperature and inside-air humidity that are measured by the inside-air temperature-humidity sensor 180, and electronic equipment power consumption measured by the power sensor 100, so as to minimize power usage effectiveness (PUE′) expressed by aforementioned equation (3).

power usage effectiveness (PUE′)=[(power consumption of the electronic equipment−power consumption of the electronic equipment fan)+(power consumption of the vaporizing-type cooling unit+power consumption of the electronic equipment fan)]/(power consumption of the electronic equipment−power consumption of the electronic equipment fan) equation (3)

A preparation method of the data table 156B employs a method similar to the preparation method of the data base 156.

The central control unit 157 is connected to the power acquisition unit 151, the temperature-humidity acquisition unit 158, the rack louver control unit 154, the outlet louver control unit 155, and the data table 156B. The central control unit 157 outputs an instruction signal and the like to the power acquisition unit 151, the temperature-humidity acquisition unit 158, the rack louver control unit 154, the outlet louver control unit 155, and the data table 156B.

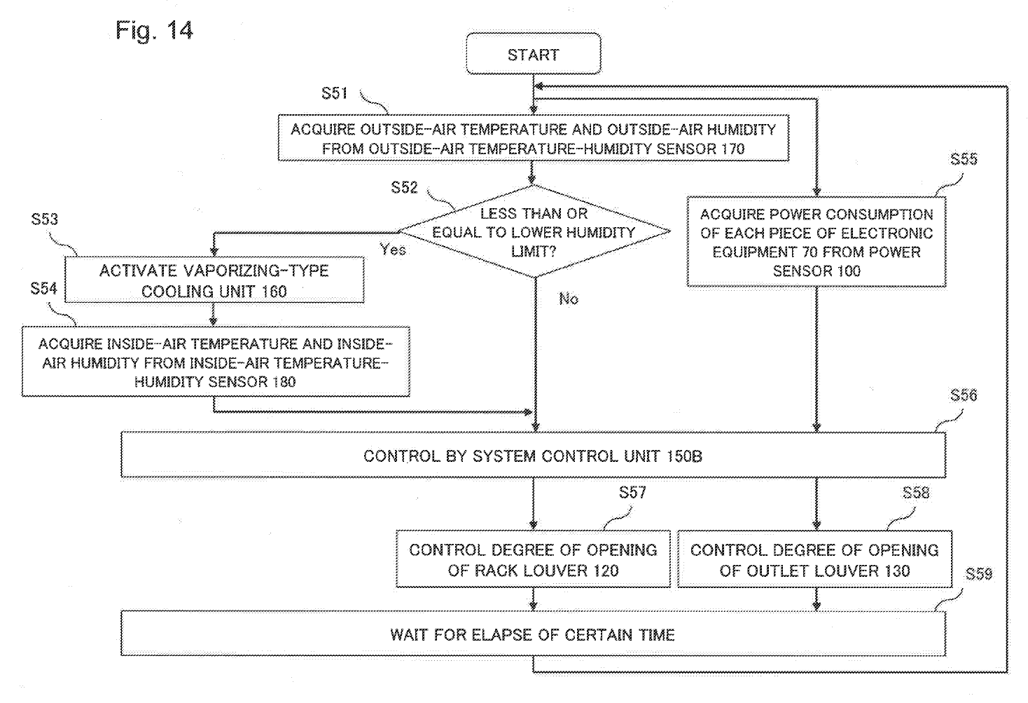

Next, an operation of the cooling device 1000B will be described. FIG. 14 is an operational flowchart of the cooling device 1000B.

As indicated in FIG. 14, first, the system control unit 150B acquires an outside-air temperature and outside-air humidity from the outside-air temperature-humidity sensor 170 (S51).

More specifically, the temperature-humidity acquisition unit 158 in the system control unit 150B acquires an outside-air temperature (a temperature of outside air external to the enclosure 10) and outside-air humidity (humidity of outside air external to the enclosure 10) that are measured by the outside-air temperature-humidity sensor 170 from the outside-air temperature-humidity sensor 170. Then, the temperature-humidity acquisition unit 158 outputs the outside-air temperature and the outside-air humidity to the central control unit 157.

Further, the power acquisition unit 151 in the system control unit 150B acquires electronic equipment power consumption (power consumption of the electronic equipment 70 in the rack 60) measured by the power sensor 100 from the power sensor 100 (S55). Then, the power acquisition unit 151 outputs the electronic equipment power consumption to the central control unit 157.

Next, the central control unit 157 determines whether or not the outside-air humidity acquired by the temperature-humidity acquisition unit 158 is less than or equal to a lower humidity limit (the measured humidity is less than or equal to a preset lower limit such as absolute humidity 10%) (S52).

When the central control unit 157 determines that the outside-air humidity acquired by the temperature-humidity acquisition unit 158 is less than or equal to the lower humidity limit (S52, Yes), the system control unit 150B performs processing in S53.

In S53, the central control unit 156 in the system control unit 150B activates the vaporizing-type cooling unit 160 (S53). Consequently, by use of vapor, the vaporizing-type cooling unit 160 raises humidity in the enclosure 10 and lowers a temperature in the enclosure 10.

Subsequently, the system control unit 150B acquires an inside-air temperature and inside-air humidity from the inside-air temperature-humidity sensor 180 (S54).

More specifically, the temperature-humidity acquisition unit 158 in the system control unit 150B acquires an inside-air temperature (a temperature of inside air internal to the enclosure 10) and inside-air humidity (humidity of inside air internal to the enclosure 10) that are measured by the inside-air temperature-humidity sensor 180 from the inside-air temperature-humidity sensor 180. Then, the temperature-humidity acquisition unit 158 outputs the inside-air temperature and the inside-air humidity to the central control unit 157.

On the other hand, when the central control unit 157 determines that the outside-air humidity acquired by the temperature-humidity acquisition unit 158 is not less than or equal to the lower humidity limit (S52, No), the system control unit 150B performs processing in S56. Additionally, the temperature-humidity acquisition unit 158 outputs the outside-air temperature and the outside-air humidity to the central control unit 157.

Next, the system control unit 150B performs predetermined control (S56). Specifically, the central control unit 157 in the system control unit 150B refers to the data table 156B. That is to say, the system control unit 150B adjusts a degree of opening of the rack louver 120 and a degree of opening of the outlet louver 130 that are prestored in the data table 156B, in accordance with the outside-air temperature and the outside-air humidity (acquired in S51), or the inside-air temperature and the inside-air humidity (acquired in S54), and the electronic equipment power consumption (acquired in S55).

More specifically, the central control unit 157 in the system control unit 150B adjusts a degree of opening of the rack louver 120 and a degree of opening of the outlet louver 130 that are prestored in the data table 156B, in accordance with the outside-air temperature and the outside-air humidity (acquired in S51), and the electronic equipment power consumption (acquired in S55).

Alternatively, the central control unit 157 in the system control unit 150B adjusts a degree of opening of the rack louver 120 and a degree of opening of the outlet louver 130 that are prestored in the data table 156B, in accordance with the inside-air temperature and the inside-air humidity (acquired in S54), and the electronic equipment power consumption (acquired in S55).

Then, the central control unit 157 outputs the respective pieces of data extracted from the data table 156B to the rack louver control unit 154 and the outlet louver control unit 155. Specifically, the central control unit 157 outputs the degree of opening of the rack louver 120 extracted from the data table 156B to the rack louver control unit 154. Further, the central control unit 157 outputs the degree of opening of the outlet louver 130 extracted from the data table 156B to the outlet louver control unit 155.

Next, the system control unit 150B controls a degree of opening of the rack louver 120 (S57) and controls a degree of opening of the outlet louver (S58).

Specifically, the rack louver control unit 154 adjusts a degree of opening of the rack louver 120 to the degree of opening of the rack louver 120 extracted from the data table 156B (S57). The outlet louver control unit 155 adjusts a degree of opening of the outlet louver 130 to the degree of opening of the outlet louver 130 extracted from the data table 156B (S58). Thus, power usage effectiveness (PUE′) can be minimized. Consequently, the electronic equipment 70 in the rack 60 can be cooled with higher energy efficiency while suppressing temperature rise in the electronic equipment 70.

Next, the cooling device 1000B waits for an elapse of a certain time (S59) and performs the processing in S51 and S55 again. As described above, the cooling device 1000B repeats the processing in S51 to S59.

The operation of the cooling device 1000B has been described above.

As described above, the cooling device 1000B according to the third exemplary embodiment of the present invention further includes the outside-air humidity sensor, the inside-air temperature sensor, and the inside-air humidity sensor, and includes the vaporizing-type cooling unit 160 in place of the blowing unit 40. The outside-air temperature sensor and the outside-air humidity sensor are included in the outside-air temperature-humidity sensor 170. The inside-air temperature sensor and the inside-air humidity sensor are included in the inside-air temperature-humidity sensor 180. The outside-air humidity sensor (outside-air temperature-humidity sensor 170) measures humidity of outside air external to the enclosure 10 as outside-air humidity. The inside-air temperature sensor (inside-air temperature-humidity sensor 180) measures a temperature of inside air internal to the enclosure 10 as an inside-air temperature. The inside-air humidity sensor (inside-air temperature-humidity sensor 180) measures humidity of inside air internal to the enclosure 10 as inside-air humidity.

When outside-air humidity measured by the outside-air humidity sensor is less than or equal to predetermined humidity, the vaporizing-type cooling unit 160, by use of vapor, raises humidity in the enclosure 10 and lowers a temperature in the enclosure 10.

Then, the system control unit 150B adjusts a degree of opening of the rack louver 120 and a degree of opening of the outlet louver 130 in accordance with an outside-air temperature and outside-air humidity, or an inside-air temperature and inside-air humidity, and electronic equipment power consumption measured by the power sensor 100. An outside-air temperature and outside-air humidity are measured by the outside-air temperature sensor and the outside-air humidity sensor. An inside-air temperature and inside-air humidity are measured by the inside-air temperature sensor and the inside-air humidity sensor.

Specifically, the system control unit 150B adjusts a degree of opening of the rack louver 120 and a degree of opening of the outlet louver 130 in accordance with an outside-air temperature and outside-air humidity that are measured by the outside-air temperature sensor and the outside-air humidity sensor, and electronic equipment power consumption measured by the power sensor 100. Alternatively, the system control unit 150B adjusts a degree of opening of the rack louver 120 and a degree of opening of the outlet louver 130 in accordance with an inside-air temperature and inside-air humidity that are measured by the inside-air temperature sensor and the inside-air humidity sensor, and electronic equipment power consumption measured by the power sensor 100.

Such a configuration is also able to provide effects similar to the effects described in the first and second exemplary embodiments.

Further, the cooling device 1000B according to the third exemplary embodiment of the present invention includes the vaporizing-type cooling unit 160. When outside-air humidity measured by the outside-air humidity sensor is less than or equal to predetermined humidity, the vaporizing-type cooling unit 160, by use of vapor, raises humidity in the enclosure 10 and lowers a temperature in the enclosure 10. Consequently, similarly to the second exemplary embodiment, frequency of malfunction and an electrostatic breakdown of the electronic equipment 70 under low outside-air relative humidity such as the winter season in Japan can be reduced.

In contrast with the first and second exemplary embodiments, the third exemplary embodiment does not include the blowing unit 40. Consequently, power consumption of the blowing unit 40 can be reduced. Further, maintenance of the blowing unit 40 is not required. Accordingly, a corresponding capital expenditure (CAPEX) can be reduced. Further, since maintenance and power consumption of the blowing unit 40 do not exist, a corresponding operating expense (OPEX) can be reduced.

Further, in addition to electronic equipment power consumption and an outside-air temperature, the cooling device 1000B also takes outside-air humidity, an inside-air temperature, and inside-air humidity into account and comprehensively adjusts a degree of opening of the rack louver 120 and a degree of opening of the outlet louver 130.

That is to say, the cooling device 1000B is able to properly change a degree of opening of the rack louver 120 and a degree of opening of the outlet louver 130 with respect to any values of an outside-air temperature, outside-air humidity, an inside-air temperature, inside-air humidity, and electronic equipment power consumption while maintaining an intake air temperature of the electronic equipment 70 (e.g. a server) within a guaranteed temperature range. Consequently, power consumption (PUE′) of the cooling equipment including the fan in the electronic equipment 70 can be minimized. Accordingly, the cooling device 1000B is able to cool the electronic equipment 70 in the rack 60 with higher energy efficiency while suppressing temperature rise in the electronic equipment 70.

Further, the cooling device 1000B according to the third exemplary embodiment of the present invention includes the data table 156B.

The data table 156B stores a degree of opening of the rack louver 120 and a degree of opening of the outlet louver 130 that are calculated, in relation to an outside-air temperature and outside-air humidity, or an inside-air temperature and inside-air humidity, and the electronic equipment power consumption measured by the power sensor 100, so as to minimize power usage effectiveness (PUE′) expressed by aforementioned equation (3). An outside-air temperature and outside-air humidity are measured by the outside-air temperature sensor and the outside-air humidity sensor. An inside-air temperature and inside-air humidity are measured by the inside-air temperature sensor and the inside-air humidity sensor.

Specifically, the data table 156B stores a degree of opening of the rack louver 120 and a degree of opening of the outlet louver 130 that are calculated, in relation to an outside-air temperature and outside-air humidity, and electronic equipment power consumption, so as to minimize power usage effectiveness (PUE′) expressed by aforementioned equation (3). Alternatively, the data table 156B stores a degree of opening of the rack louver 120 and a degree of opening of the outlet louver 130 that are calculated, in relation to an inside-air temperature and inside-air humidity, and electronic equipment power consumption, so as to minimize power usage effectiveness (PUE′) expressed by aforementioned equation (3).

Then, the system control unit 150B adjusts a degree of opening of the rack louver 120 and a degree of opening of the outlet louver 130 to a degree of opening of the rack louver 120 and a degree of opening of the outlet louver 130 that are stored in the data table 156B, in accordance with an outside-air temperature and outside-air humidity, or an inside-air temperature and inside-air humidity, and electronic equipment power consumption.

Specifically, the system control unit 150B adjusts a degree of opening of the rack louver 120 and a degree of opening of the outlet louver 130 to a degree of opening of the rack louver 120 and a degree of opening of the outlet louver 130 that are stored in the data table 156B, in accordance with an outside-air temperature and outside-air humidity, and electronic equipment power consumption. Alternatively, the system control unit 150B adjusts a degree of opening of the rack louver 120 and a degree of opening of the outlet louver 130 to a degree of opening of the rack louver 120 and a degree of opening of the outlet louver 130 that are stored in the data table 156B, in accordance with an inside-air temperature and inside-air humidity, and electronic equipment power consumption.

Consequently, power consumption (PUE′) of the cooling equipment including the fan in the electronic equipment 70 can always be minimized. Accordingly, the cooling device 1000B is able to cool the electronic equipment 70 in the rack 60 with higher energy efficiency while suppressing temperature rise in the electronic equipment 70.

The cooling device 1000B according to the third exemplary embodiment of the present invention may include a regression line storage unit in place of the data table 156B.

The regression line storage unit stores a regression line defining a relation between a degree of opening of the rack louver 120 and a degree of opening of the outlet louver 130 that are calculated, in relation to an outside-air temperature and outside-air humidity, or an inside-air temperature and inside-air humidity, and electronic equipment power consumption measured by the power sensor 100, so as to minimize power usage effectiveness (PUE′) expressed by equation (3). Specifically, at a certain temperature and certain humidity, by performing multiple regression analysis with motive power of the blowing unit 40, a degree of opening of the rack louver 120, and a degree of opening of the outlet louver 130 as explanatory variables and PUE′ as a response variable, coefficients of the respective explanatory variables can be acquired, and a regression line can be obtained.
An outside-air temperature and outside-air humidity are measured by the outside-air temperature sensor and the outside-air humidity sensor. An inside-air temperature and inside-air humidity are measured by the inside-air temperature sensor and the inside-air humidity sensor.

Specifically, the regression line storage unit stores a regression line defining a relation between a degree of opening of the rack louver 120 and a degree of opening of the outlet louver 130 that are calculated, in relation to an outside-air temperature and outside-air humidity, and electronic equipment power consumption, so as to minimize power usage effectiveness (PUE′) expressed by equation (3). Alternatively, the regression line storage unit stores a regression line defining a relation between a degree of opening of the rack louver 120 and a degree of opening of the outlet louver 130 that are calculated, in relation to an inside-air temperature and inside-air humidity, and electronic equipment power consumption, so as to minimize power usage effectiveness (PUE′) expressed by equation (3).

Then, the system control unit 150B adjusts a degree of opening of the rack louver 120 and a degree of opening of the outlet louver 130 by use of the regression line stored in the regression line storage unit, in accordance with an outside-air temperature and outside-air humidity, or an inside-air temperature and inside-air humidity, and electronic equipment power consumption.

Specifically, the system control unit 150B adjusts a degree of opening of the rack louver 120 and a degree of opening of the outlet louver 130 by use of the regression line stored in the regression line storage unit, in accordance with an outside-air temperature and outside-air humidity, and electronic equipment power consumption. Alternatively, the system control unit 150B adjusts a degree of opening of the rack louver 120 and a degree of opening of the outlet louver 130 by use of the regression line stored in the regression line storage unit, in accordance with an inside-air temperature and inside-air humidity, and electronic equipment power consumption.

The configuration also provides an effect similar to the case using the data table 156B.

### Example

An example of the cooling device 1000 according to the first exemplary embodiment will be described.

Dimensions of the enclosure 10 (container) were 1.3 m wide, 2.4 m deep, and 2.5 m high. Dimensions of the rack 60 were 0.6 m wide, 1 m deep, and 2 m high. Two racks 60 were prepared and housed in the enclosure 10. Dimensions of the rack louver 120 were 1 m wide and 0.3 m high.

In such an environment (module-type data center environment), total heat generated by the rack 60 was 20 kW (heat generated by one rack 60 being 20 kW, and heat generated by the other rack 60 being 0 kW). Further, under a condition of an outside-air temperature of 20° C. and humidity of 50%, a degree of influence of each parameter on power consumption of the fan in the electronic equipment 70 (a server) was examined.

The outside-air temperature of 20° C. and the humidity of 50% are preferable as an intake air temperature and intake air humidity, being a temperature and humidity of air taken into the electronic equipment 70 (a server), respectively. Accordingly, in a conventional common control method of a cooling device, the rack louver is closed so that exhaust heat from electronic equipment (a server) does not mix into the intake side of the electronic equipment 70. The reason is that, when the rack louver is kept open and exhaust heat from the electronic equipment mixes into the intake side of the electronic equipment 70, an intake air temperature of the electronic equipment 70 may go out of a guaranteed temperature range guaranteeing normal operation of the electronic equipment 70.

When the rack louver 120 was closed, a pressure loss increased, and therefore, in this example, total power consumption of all the fans in the electronic equipment 70 housed in one rack 60 was approximately 460 W.

On the other hand, when the rack louver 120 was open, total power consumption of all the fans in the electronic equipment 70 housed in one rack 60 was approximately 300 W.

That is to say, when the rack louver 120 was closed, the power consumption of the fans in the electronic equipment 70 increased by about 50% compared with the case when the rack louver 120 was open.

Accordingly, influence of the power consumption of the fans in the electronic equipment 70 (a server) should be properly benchmarked by PUE′.

Under the aforementioned condition, the rack louver 120 is fully closed in a common control method of a cooling device. By contrast, a degree of opening of the rack louver 120 is fully open in the control method of the cooling device 1000 according to the present invention.

Total power consumption of the entire cooling device (also referred to as cooling power) including power consumption of the fans in the electronic equipment 70 was approximately 1450 W by the common control method of a cooling device. By contrast, when the control method of the cooling device 1000 according to the present invention was used, the power consumption of the entire cooling device 1000 including power consumption of the fans in the electronic equipment 70 was approximately 1300 W.

That is to say, an improvement of approximately 10% reduction in power consumption of the entire cooling device was achieved. This is an extremely important result in terms of energy efficiency of the cooling device.

Further, in the cooling device 1000 according to the present invention, control of the cooling device 1000 also includes motive power of the blowing unit 40 (a revolving speed in this case). Accordingly, as for a blowing amount of the blowing unit 40 being excessive in a common cooling device, an optimum value can be obtained with respect to an environment external to the cooling device 1000 (an outside air environment) and heat generated by the electronic equipment 70 in the rack 60. Thus, the cooling device 1000 is able to achieve further reduction of power consumption.

The aforementioned exemplary embodiments may be described in part or in whole as the following Supplementary notes but are not limited thereto.

### [Supplementary Note 1]

A cooling device including:

an enclosure including an inlet and an outlet;

a blowing unit being provided in the enclosure, taking outside air external to the enclosure into the enclosure through the inlet, and discharging inside air internal to the enclosure to outside the enclosure through the outlet;

an outside-air temperature sensor measuring a temperature of outside air external to the enclosure as an outside-air temperature;

an electronic equipment housing enclosure being provided between the inlet and the outlet in the enclosure and housing electronic equipment;

an electronic equipment fan being provided in the electronic equipment, taking outside air external to the electronic equipment housing enclosure into the electronic equipment housing enclosure, and discharging inside air internal to the electronic equipment housing enclosure to outside the electronic equipment housing enclosure;

a power sensor measuring power consumption of the electronic equipment in the electronic equipment housing enclosure as electronic equipment power consumption;

a first opening-closing mechanism unit being provided between the inlet and the outlet in the enclosure and on an upper side of the electronic equipment housing enclosure in the enclosure so as to separate air taken into the electronic equipment housing enclosure and air discharged from the electronic equipment housing enclosure, and controlling an air flow of outside air external to the enclosure taken into the electronic equipment housing enclosure, flowing from the inlet to the outlet;

a second opening-closing mechanism unit being provided on the outlet and controlling an air flow of inside air internal to the enclosure flowing out from the outlet to outside the enclosure; and

a system control unit adjusting motive power of the blowing unit, a degree of opening of the first opening-closing mechanism unit, and a degree of opening of the second opening-closing mechanism unit in accordance with the outside-air temperature measured by the outside-air temperature sensor and the electronic equipment power consumption measured by the power sensor.

### [Supplementary Note 2]

The cooling device according to Supplementary note 1, further including

a data table storing motive power of the blowing unit, a degree of opening of the first opening-closing mechanism unit, and a degree of opening of the second opening-closing mechanism unit that are calculated, in relation to the outside-air temperature measured by the outside-air temperature sensor and the electronic equipment power consumption measured by the power sensor, so as to minimize power usage effectiveness below, wherein

the power usage effectiveness is expressed by

power usage effectiveness=[(power consumption of the electronic equipment−power consumption of the electronic equipment fan)+(power consumption of the blowing unit+power consumption of the electronic equipment fan)]/(power consumption of the electronic equipment−power consumption of the electronic equipment fan), and

the system control unit adjusts motive power of the blowing unit, a degree of opening of the first opening-closing mechanism unit, and a degree of opening of the second opening-closing mechanism unit to motive power of the blowing unit, a degree of opening of the first opening-closing mechanism unit, and a degree of opening of the second opening-closing mechanism unit that are stored in the data table, in accordance with the outside-air temperature measured by the outside-air temperature sensor and the electronic equipment power consumption measured by the power sensor.

### [Supplementary Note 3]

The cooling device according to Supplementary note 1, further including

a regression line storage unit storing a regression line defining a relation between motive power of the blowing unit, a degree of opening of the first opening-closing mechanism unit, and a degree of opening of the second opening-closing mechanism unit that are calculated, in relation to the outside-air temperature measured by the outside-air temperature sensor and the electronic equipment power consumption measured by the power sensor, so as to minimize power usage effectiveness below, wherein

the power usage effectiveness is expressed by

power usage effectiveness=[(power consumption of the electronic equipment−power consumption of the electronic equipment fan)+(power consumption of the blowing unit+power consumption of the electronic equipment fan)]/(power consumption of the electronic equipment−power consumption of the electronic equipment fan), and

the system control unit adjusts motive power of the blowing unit, a degree of opening of the first opening-closing mechanism unit, and a degree of opening of the second opening-closing mechanism unit by use of the regression line stored in the regression line storage unit, in accordance with the outside-air temperature measured by the outside-air temperature sensor and the electronic equipment power consumption measured by the power sensor.

### [Supplementary Note 4]

The cooling device according to Supplementary note 1, further including:

an outside-air humidity sensor measuring humidity of outside air external to the enclosure as outside-air humidity;

an inside-air temperature sensor measuring a temperature of inside air internal to the enclosure as an inside-air temperature;

an inside-air humidity sensor measuring humidity of inside air internal to the enclosure as inside-air humidity; and

a vaporizing-type cooling unit, by use of vapor, raising humidity in the enclosure and lowering a temperature in the enclosure, when the outside-air humidity measured by the outside-air humidity sensor is less than or equal to predetermined humidity, wherein

a system control unit adjusts motive power of the blowing unit, a degree of opening of the first opening-closing mechanism unit, and a degree of opening of the second opening-closing mechanism unit in accordance with the outside-air temperature and the outside-air humidity that are measured by the outside-air temperature sensor and the outside-air humidity sensor, or the inside-air temperature and the inside-air humidity that are measured by the inside-air temperature sensor and the inside-air humidity sensor, and the electronic equipment power consumption measured by the power sensor.

### [Supplementary Note 5]

The cooling device according to Supplementary note 4, further including

a data table storing motive power of the blowing unit, a degree of opening of the first opening-closing mechanism unit, and a degree of opening of the second opening-closing mechanism unit that are calculated, in relation to the outside-air temperature and the outside-air humidity that are measured by the outside-air temperature sensor and the outside-air humidity sensor, or the inside-air temperature and the inside-air humidity that are measured by the inside-air temperature sensor and the inside-air humidity sensor, and the electronic equipment power consumption measured by the power sensor, so as to minimize power usage effectiveness below, wherein

the power usage effectiveness is expressed by

power usage effectiveness=[(power consumption of the electronic equipment−power consumption of the electronic equipment fan)+(power consumption of the blowing unit+power consumption of the vaporizing-type cooling unit+power consumption of the electronic equipment fan)]/(power consumption of the electronic equipment−power consumption of the electronic equipment fan), and

the system control unit adjusts motive power of the blowing unit, a degree of opening of the first opening-closing mechanism unit, and a degree of opening of the second opening-closing mechanism unit to motive power of the blowing unit, a degree of opening of the first opening-closing mechanism unit, and a degree of opening of the second opening-closing mechanism unit that are stored in the data table, in accordance with the outside-air temperature and the outside-air humidity that are measured by the outside-air temperature sensor and the outside-air humidity sensor, or the inside-air temperature and the inside-air humidity that are measured by the inside-air temperature sensor and the inside-air humidity sensor, and the electronic equipment power consumption measured by the power sensor.

### [Supplementary Note 6]

The cooling device according to Supplementary note 4, further including

a regression line storage unit storing a regression line defining a relation between motive power of the blowing unit, a degree of opening of the first opening-closing mechanism unit, and a degree of opening of the second opening-closing mechanism unit that are calculated, in relation to the outside-air temperature and the outside-air humidity that are measured by the outside-air temperature sensor and the outside-air humidity sensor, or the inside-air temperature and the inside-air humidity that are measured by the inside-air temperature sensor and the inside-air humidity sensor, and the electronic equipment power consumption measured by the power sensor, so as to minimize power usage effectiveness below, wherein

the power usage effectiveness is expressed by

power usage effectiveness=[(power consumption of the electronic equipment−power consumption of the electronic equipment fan)+(power consumption of the blowing unit+power consumption of the vaporizing-type cooling unit+power consumption of the electronic equipment fan)]/(power consumption of the electronic equipment−power consumption of the electronic equipment fan), and

the system control unit adjusts motive power of the blowing unit, a degree of opening of the first opening-closing mechanism unit, and a degree of opening of the second opening-closing mechanism unit by use of the regression line stored in the regression line storage unit, in accordance with the outside-air temperature and the outside-air humidity that are measured by the outside-air temperature sensor and the outside-air humidity sensor, or the inside-air temperature and the inside-air humidity that are measured by the inside-air temperature sensor and the inside-air humidity sensor, and the electronic equipment power consumption measured by the power sensor.

### [Supplementary Note 7]

The cooling device according to Supplementary note 1, including, in place of the blowing unit:

an outside-air humidity sensor measuring humidity of outside air external to the enclosure as outside-air humidity;

an inside-air temperature sensor measuring a temperature of inside air internal to the enclosure as an inside-air temperature;

an inside-air humidity sensor measuring humidity of inside air internal to the enclosure as inside-air humidity; and

a vaporizing-type cooling unit, by use of vapor, raising humidity in the enclosure and lowering a temperature in the enclosure, when the outside-air humidity measured by the outside-air humidity sensor is less than or equal to predetermined humidity, wherein

a system control unit adjusts a degree of opening of the first opening-closing mechanism unit and a degree of opening of the second opening-closing mechanism unit in accordance with the outside-air temperature and the outside-air humidity that are measured by the outside-air temperature sensor and the outside-air humidity sensor, or the inside-air temperature and the inside-air humidity that are measured by the inside-air temperature sensor and the inside-air humidity sensor, and the electronic equipment power consumption measured by the power sensor.

### [Supplementary Note 8]

The cooling device according to Supplementary note 7, further including

a data table storing motive power of the blowing unit, a degree of opening of the first opening-closing mechanism unit, and a degree of opening of the second opening-closing mechanism unit that are calculated, in relation to the outside-air temperature and the outside-air humidity that are measured by the outside-air temperature sensor and the outside-air humidity sensor, or the inside-air temperature and the inside-air humidity that are measured by the inside-air temperature sensor and the inside-air humidity sensor, and the electronic equipment power consumption measured by the power sensor, so as to minimize power usage effectiveness below, wherein

the power usage effectiveness is expressed by

power usage effectiveness=[(power consumption of the electronic equipment−power consumption of the electronic equipment fan)+(power consumption of the vaporizing-type cooling unit+power consumption of the electronic equipment fan)]/(power consumption of the electronic equipment−power consumption of the electronic equipment fan), and

the system control unit adjusts a degree of opening of the first opening-closing mechanism unit and a degree of opening of the second opening-closing mechanism unit to a degree of opening of the first opening-closing mechanism unit and a degree of opening of the second opening-closing mechanism unit that are stored in the data table, in accordance with the outside-air temperature and the outside-air humidity that are measured by the outside-air temperature sensor and the outside-air humidity sensor, or the inside-air temperature and the inside-air humidity that are measured by the inside-air temperature sensor and the inside-air humidity sensor, and the electronic equipment power consumption measured by the power sensor.

### [Supplementary Note 9]

The cooling device according to Supplementary note 7, further including

a regression line storage unit storing a regression line defining a relation between a degree of opening of the first opening-closing mechanism unit and a degree of opening of the second opening-closing mechanism unit that are calculated, in relation to the outside-air temperature and the outside-air humidity that are measured by the outside-air temperature sensor and the outside-air humidity sensor, or the inside-air temperature and the inside-air humidity that are measured by the inside-air temperature sensor and the inside-air humidity sensor, and the electronic equipment power consumption measured by the power sensor, so as to minimize power usage effectiveness below, wherein

the power usage effectiveness is expressed by

power usage effectiveness=[(power consumption of the electronic equipment−power consumption of the electronic equipment fan)+(power consumption of the vaporizing-type cooling unit+power consumption of the electronic equipment fan)]/(power consumption of the electronic equipment−power consumption of the electronic equipment fan), and

the system control unit adjusts a degree of opening of the first opening-closing mechanism unit and a degree of opening of the second opening-closing mechanism unit by use of the regression line stored in the regression line storage unit, in accordance with the outside-air temperature and the outside-air humidity that are measured by the outside-air temperature sensor and the outside-air humidity sensor, or the inside-air temperature and the inside-air humidity that are measured by the inside-air temperature sensor and the inside-air humidity sensor, and the electronic equipment power consumption measured by the power sensor.

### [Supplementary Note 10]

A control method of a cooling device including:

an enclosure including an inlet and an outlet;

a blowing unit being provided in the enclosure, taking outside air external to the enclosure into the enclosure through the inlet, and discharging inside air internal to the enclosure to outside the enclosure through the outlet;

an outside-air temperature sensor measuring a temperature of outside air external to the enclosure as an outside-air temperature;

an electronic equipment housing enclosure being provided between the inlet and the outlet in the enclosure and housing electronic equipment;

an electronic equipment fan being provided in the electronic equipment, taking outside air external to the electronic equipment housing enclosure into the electronic equipment housing enclosure, and discharging inside air internal to the electronic equipment housing enclosure to outside the electronic equipment housing enclosure;

a power sensor measuring power consumption of the electronic equipment in the electronic equipment housing enclosure as electronic equipment power consumption;

a first opening-closing mechanism unit being provided between the inlet and the outlet in the enclosure and on an upper side of the electronic equipment housing enclosure in the enclosure so as to separate air taken into the electronic equipment housing enclosure and air discharged from the electronic equipment housing enclosure, and controlling an air flow of outside air external to the enclosure taken into the electronic equipment housing enclosure, flowing from the inlet to the outlet; and

a second opening-closing mechanism unit being provided on the outlet and controlling an air flow of inside air internal to the enclosure flowing out from the outlet to outside the enclosure,

the method including adjusting motive power of the blowing unit, a degree of opening of the first opening-closing mechanism unit, and a degree of opening of the second opening-closing mechanism unit in accordance with the outside-air temperature measured by the outside-air temperature sensor and the electronic equipment power consumption measured by the power sensor.

### [Supplementary Note 11]

A control program of a cooling device including:

an enclosure including an inlet and an outlet;

a blowing unit being provided in the enclosure, taking outside air external to the enclosure into the enclosure through the inlet, and discharging inside air internal to the enclosure to outside the enclosure through the outlet;

an outside-air temperature sensor measuring a temperature of outside air external to the enclosure as an outside-air temperature;

an electronic equipment housing enclosure being provided between the inlet and the outlet in the enclosure and housing electronic equipment;

an electronic equipment fan being provided in the electronic equipment, taking outside air external to the electronic equipment housing enclosure into the electronic equipment housing enclosure, and discharging inside air internal to the electronic equipment housing enclosure to outside the electronic equipment housing enclosure;

a power sensor measuring power consumption of the electronic equipment in the electronic equipment housing enclosure as electronic equipment power consumption;

a first opening-closing mechanism unit being provided between the inlet and the outlet in the enclosure and on an upper side of the electronic equipment housing enclosure in the enclosure so as to separate air taken into the electronic equipment housing enclosure and air discharged from the electronic equipment housing enclosure, and controlling an air flow of outside air external to the enclosure taken into the electronic equipment housing enclosure, flowing from the inlet to the outlet; and

a second opening-closing mechanism unit being provided on the outlet and controlling an air flow of inside air internal to the enclosure flowing out from the outlet to outside the enclosure,

the program causing a computer to perform control of adjusting motive power of the blowing unit, a degree of opening of the first opening-closing mechanism unit, and a degree of opening of the second opening-closing mechanism unit in accordance with the outside-air temperature measured by the outside-air temperature sensor and the electronic equipment power consumption measured by the power sensor.

### [Supplementary Note 12]

A storage medium storing a control program of a cooling device including:

an enclosure including an inlet and an outlet;

a blowing unit being provided in the enclosure, taking outside air external to the enclosure into the enclosure through the inlet, and discharging inside air internal to the enclosure to outside the enclosure through the outlet;

an outside-air temperature sensor measuring a temperature of outside air external to the enclosure as an outside-air temperature;

an electronic equipment housing enclosure being provided between the inlet and the outlet in the enclosure and housing electronic equipment;

an electronic equipment fan being provided in the electronic equipment, taking outside air external to the electronic equipment housing enclosure into the electronic equipment housing enclosure, and discharging inside air internal to the electronic equipment housing enclosure to outside the electronic equipment housing enclosure;

a power sensor measuring power consumption of the electronic equipment in the electronic equipment housing enclosure as electronic equipment power consumption;

a first opening-closing mechanism unit being provided between the inlet and the outlet in the enclosure and on an upper side of the electronic equipment housing enclosure in the enclosure so as to separate air taken into the electronic equipment housing enclosure and air discharged from the electronic equipment housing enclosure, and controlling an air flow of outside air external to the enclosure taken into the electronic equipment housing enclosure, flowing from the inlet to the outlet; and

a second opening-closing mechanism unit being provided on the outlet and controlling an air flow of inside air internal to the enclosure flowing out from the outlet to outside the enclosure,

the program causing a computer to perform control of adjusting motive power of the blowing unit, a degree of opening of the first opening-closing mechanism unit, and a degree of opening of the second opening-closing mechanism unit in accordance with the outside-air temperature measured by the outside-air temperature sensor and the electronic equipment power consumption measured by the power sensor.

As above, the present invention has been described based on the exemplary embodiments. An exemplary embodiment is just an illustration, and various kinds of changes, addition or subtraction and combinations may be added to each of the above-mentioned exemplary embodiments unless it deviates from the main points of the present invention. It is understood by a person skilled in the art that modification made by adding such changes, addition/subtraction and combinations are also included in the scope of the present invention.

This application claims priority based on Japanese application Japanese Patent Application No. 2014-171528, filed on Aug. 26, 2016, the disclosure of which is incorporated herein in its entirety.

### REFERENCE SIGNS LIST

10 Enclosure
20 Inlet
30 Outlet
40 Blowing unit
50 Outside-air temperature sensor
60 Rack
70 Electronic equipment
80 Electronic equipment fan
90 Rack inlet temperature sensor
100 Power sensor
110 Electronic equipment accessory
120 Rack louver
130 Outlet louver
140 Louver system
141 Blade
142 Louver actuation unit
150, 150A, 150B System control unit
151 Power acquisition unit
152 Temperature acquisition unit
153 Blowing control unit
154 Rack louver control unit
155 Outlet louver control unit
156, 156A, 156B Data table
157 Central control unit
158 Temperature-humidity acquisition unit
160 Vaporizing-type cooling unit
170 Outside-air temperature-humidity sensor
180 Inside-air temperature-humidity sensor
1000, 1000A, 1000B Cooling device

1. A cooling device comprising:
an enclosure including an inlet and an outlet;
a blowing unit being provided in the enclosure, taking outside air external to the enclosure into the enclosure through the inlet, and discharging inside air internal to the enclosure to outside the enclosure through the outlet;
an outside-air temperature sensor measuring a temperature of outside air external to the enclosure as an outside-air temperature;
an electronic equipment housing enclosure being provided between the inlet and the outlet in the enclosure and housing electronic equipment;
an electronic equipment fan being provided in the electronic equipment, taking outside air external to the electronic equipment housing enclosure into the electronic equipment housing enclosure, and discharging inside air internal to the electronic equipment housing enclosure to outside the electronic equipment housing enclosure;
a power sensor measuring power consumption of the electronic equipment in the electronic equipment housing enclosure as electronic equipment power consumption;
a first opening-closing mechanism unit being provided between the inlet and the outlet in the enclosure and on an upper side of the electronic equipment housing enclosure in the enclosure so as to separate air taken into the electronic equipment housing enclosure and air discharged from the electronic equipment housing enclosure, and controlling an air flow of outside air external to the enclosure taken into the electronic equipment housing enclosure, flowing from the inlet to the outlet;
a second opening-closing mechanism unit being provided on the outlet and controlling an air flow of inside air internal to the enclosure, flowing out from the outlet to outside the enclosure; and
a system control unit adjusting motive power of the blowing unit, a degree of opening of the first opening-closing mechanism unit, and a degree of opening of the second opening-closing mechanism unit in accordance with the outside-air temperature measured by the outside-air temperature sensor and the electronic equipment power consumption measured by the power sensor.

2. The cooling device according to claim 1, further comprising
a data table storing motive power of the blowing unit, a degree of opening of the first opening-closing mechanism unit, and a degree of opening of the second opening-closing mechanism unit that are calculated, in relation to the outside-air temperature measured by the outside-air temperature sensor and the electronic equipment power consumption measured by the power sensor, so as to minimize power usage effectiveness below, wherein
the power usage effectiveness is expressed by
power usage effectiveness=[(power consumption of the electronic equipment−power consumption of the electronic equipment fan)+(power consumption of the blowing unit+power consumption of the electronic equipment fan)]/(power consumption of the electronic equipment−power consumption of the electronic equipment fan), and
the system control unit adjusts motive power of the blowing unit, a degree of opening of the first opening-closing mechanism unit, and a degree of opening of the second opening-closing mechanism unit to motive power of the blowing unit, a degree of opening of the first opening-closing mechanism unit, and a degree of opening of the second opening-closing mechanism unit that are stored in the data table, in accordance with the outside-air temperature measured by the outside-air temperature sensor and the electronic equipment power consumption measured by the power sensor.

3. The cooling device according to claim 1, further comprising
a regression line storage unit storing a regression line defining a relation between motive power of the blowing unit, a degree of opening of the first opening-closing mechanism unit, and a degree of opening of the second opening-closing mechanism unit that are calculated, in relation to the outside-air temperature measured by the outside-air temperature sensor and the electronic equipment power consumption measured by the power sensor, so as to minimize power usage effectiveness below, wherein
the power usage effectiveness is expressed by
power usage effectiveness=[(power consumption of the electronic equipment−power consumption of the electronic equipment fan)+(power consumption of the blowing unit+power consumption of the electronic equipment fan)]/(power consumption of the electronic equipment−power consumption of the electronic equipment fan), and
the system control unit adjusts motive power of the blowing unit, a degree of opening of the first opening-closing mechanism unit, and a degree of opening of the second opening-closing mechanism unit by use of the regression line stored in the regression line storage unit, in accordance with the outside-air temperature measured by the outside-air temperature sensor and the electronic equipment power consumption measured by the power sensor.

4. The cooling device according to claim 1, further comprising:
an outside-air humidity sensor measuring humidity of outside air external to the enclosure as outside-air humidity;
an inside-air temperature sensor measuring a temperature of inside air internal to the enclosure as an inside-air temperature;
an inside-air humidity sensor measuring humidity of inside air internal to the enclosure as inside-air humidity; and
a vaporizing-type cooling unit, by use of vapor, raising humidity in the enclosure and lowering a temperature in the enclosure, when the outside-air humidity measured by the outside-air humidity sensor is less than or equal to predetermined humidity, wherein
a system control unit adjusts motive power of the blowing unit, a degree of opening of the first opening-closing mechanism unit, and a degree of opening of the second opening-closing mechanism unit in accordance with the outside-air temperature and the outside-air humidity that are measured by the outside-air temperature sensor and the outside-air humidity sensor, or the inside-air temperature and the inside-air humidity that are measured by the inside-air temperature sensor and the inside-air humidity sensor, and the electronic equipment power consumption measured by the power sensor.

5. The cooling device according to claim 4, further comprising
a data table storing motive power of the blowing unit, a degree of opening of the first opening-closing mechanism unit, and a degree of opening of the second opening-closing mechanism unit that are calculated, in relation to the outside-air temperature and the outside-air humidity that are measured by the outside-air temperature sensor and the outside-air humidity sensor, or the inside-air temperature and the inside-air humidity that are measured by the inside-air temperature sensor and the inside-air humidity sensor, and the electronic equipment power consumption measured by the power sensor, so as to minimize power usage effectiveness below, wherein
the power usage effectiveness is expressed by
power usage effectiveness=[(power consumption of the electronic equipment−power consumption of the electronic equipment fan)+(power consumption of the blowing unit+power consumption of the vaporizing-type cooling unit+power consumption of the electronic equipment fan)]/(power consumption of the electronic equipment−power consumption of the electronic equipment fan), and
the system control unit adjusts motive power of the blowing unit, a degree of opening of the first opening-closing mechanism unit, and a degree of opening of the second opening-closing mechanism unit to motive power of the blowing unit, a degree of opening of the first opening-closing mechanism unit, and a degree of opening of the second opening-closing mechanism unit that are stored in the data table, in accordance with the outside-air temperature and the outside-air humidity that are measured by the outside-air temperature sensor and the outside-air humidity sensor, or the inside-air temperature and the inside-air humidity that are measured by the inside-air temperature sensor and the inside-air humidity sensor, and the electronic equipment power consumption measured by the power sensor.

6. The cooling device according to claim 4, further comprising
a regression line storage unit storing a regression line defining a relation between motive power of the blowing unit, a degree of opening of the first opening-closing mechanism unit, and a degree of opening of the second opening-closing mechanism unit that are calculated, in relation to the outside-air temperature and the outside-air humidity that are measured by the outside-air temperature sensor and the outside-air humidity sensor, or the inside-air temperature and the inside-air humidity that are measured by the inside-air temperature sensor and the inside-air humidity sensor, and the electronic equipment power consumption measured by the power sensor, so as to minimize power usage effectiveness below, wherein
the power usage effectiveness is expressed by
power usage effectiveness=[(power consumption of the electronic equipment−power consumption of the electronic equipment fan)+(power consumption of the blowing unit+power consumption of the vaporizing-type cooling unit+power consumption of the electronic equipment fan)]/(power consumption of the electronic equipment−power consumption of the electronic equipment fan), and
the system control unit adjusts motive power of the blowing unit, a degree of opening of the first opening-closing mechanism unit, and a degree of opening of the second opening-closing mechanism unit by use of the regression line stored in the regression line storage unit, in accordance with the outside-air temperature and the outside-air humidity that are measured by the outside-air temperature sensor and the outside-air humidity sensor, or the inside-air temperature and the inside-air humidity that are measured by the inside-air temperature sensor and the inside-air humidity sensor, and the electronic equipment power consumption measured by the power sensor.

7. The cooling device according to claim 1, comprising, in place of the blowing unit:
an outside-air humidity sensor measuring humidity of outside air external to the enclosure as outside-air humidity;
an inside-air temperature sensor measuring a temperature of inside air internal to the enclosure as an inside-air temperature;
an inside-air humidity sensor measuring humidity of inside air internal to the enclosure as inside-air humidity; and
a vaporizing-type cooling unit, by use of vapor, raising humidity in the enclosure and lowering a temperature in the enclosure, when the outside-air humidity measured by the outside-air humidity sensor is less than or equal to predetermined humidity, wherein
a system control unit adjusts a degree of opening of the first opening-closing mechanism unit and a degree of opening of the second opening-closing mechanism unit in accordance with the outside-air temperature and the outside-air humidity that are measured by the outside-air temperature sensor and the outside-air humidity sensor, or the inside-air temperature and the inside-air humidity that are measured by the inside-air temperature sensor and the inside-air humidity sensor, and the electronic equipment power consumption measured by the power sensor.

8. The cooling device according to claim 9, further comprising
a data table storing motive power of the blowing unit, a degree of opening of the first opening-closing mechanism unit, and a degree of opening of the second opening-closing mechanism unit that are calculated, in relation to the outside-air temperature and the outside-air humidity that are measured by the outside-air temperature sensor and the outside-air humidity sensor, or the inside-air temperature and the inside-air humidity that are measured by the inside-air temperature sensor and the inside-air humidity sensor, and the electronic equipment power consumption measured by the power sensor, so as to minimize power usage effectiveness below, wherein
the power usage effectiveness is expressed by
power usage effectiveness=[(power consumption of the electronic equipment−power consumption of the electronic equipment fan)+(power consumption of the vaporizing-type cooling unit+power consumption of the electronic equipment fan)]/(power consumption of the electronic equipment−power consumption of the electronic equipment fan), and
the system control unit adjusts a degree of opening of the first opening-closing mechanism unit and a degree of opening of the second opening-closing mechanism unit to a degree of opening of the first opening-closing mechanism unit and a degree of opening of the second opening-closing mechanism unit that are stored in the data table, in accordance with the outside-air temperature and the outside-air humidity that are measured by the outside-air temperature sensor and the outside-air humidity sensor, or the inside-air temperature and the inside-air humidity that are measured by the inside-air temperature sensor and the inside-air humidity sensor, and the electronic equipment power consumption measured by the power sensor.

9. A control method of a cooling device including:
an enclosure including an inlet and an outlet;
a blowing unit being provided in the enclosure, taking outside air external to the enclosure into the enclosure through the inlet, and discharging inside air internal to the enclosure to outside the enclosure through the outlet;
an outside-air temperature sensor measuring a temperature of outside air external to the enclosure as an outside-air temperature;
an electronic equipment housing enclosure being provided between the inlet and the outlet in the enclosure and housing electronic equipment;
an electronic equipment housing enclosure fan being provided in the electronic equipment, taking outside air external to the electronic equipment housing enclosure into the electronic equipment housing enclosure, and discharging inside air internal to the electronic equipment housing enclosure to outside the electronic equipment housing enclosure;
a power sensor measuring power consumption of the electronic equipment in the electronic equipment housing enclosure as electronic equipment power consumption;
a first opening-closing mechanism unit being provided between the inlet and the outlet in the enclosure and on an upper side of the electronic equipment housing enclosure in the enclosure so as to separate air taken into the electronic equipment housing enclosure and air discharged from the rack, and controlling an air flow of outside air external to the enclosure taken into the electronic equipment housing enclosure, flowing from the inlet to the outlet; and
a second opening-closing mechanism unit being provided on the outlet and controlling an air flow of inside air internal to the enclosure, flowing out from the outlet to outside the enclosure,
the control method comprising adjusting motive power of the blowing unit, a degree of opening of the first opening-closing mechanism unit, and a degree of opening of the second opening-closing mechanism unit in accordance with the outside-air temperature measured by the outside-air temperature sensor and the electronic equipment power consumption measured by the power sensor.

10. A storage medium storing a control program of a cooling device including:
an enclosure including an inlet and an outlet;
a blowing unit being provided in the enclosure, taking outside air external to the enclosure into the enclosure through the inlet, and discharging inside air internal to the enclosure to outside the enclosure through the outlet;
an outside-air temperature sensor measuring a temperature of outside air external to the enclosure as an outside-air temperature;
an electronic equipment housing enclosure being provided between the inlet and the outlet in the enclosure and housing electronic equipment;
an electronic equipment fan being provided in the electronic equipment, taking outside air external to the electronic equipment housing enclosure into the electronic equipment housing enclosure, and discharging inside air internal to the electronic equipment housing enclosure to outside the electronic equipment housing enclosure;
a power sensor measuring power consumption of the electronic equipment in the electronic equipment housing enclosure as electronic equipment power consumption;
a first opening-closing mechanism unit being provided between the inlet and the outlet in the enclosure and on an upper side of the electronic equipment housing enclosure in the enclosure so as to separate air taken into the electronic equipment housing enclosure and air discharged from the electronic equipment housing enclosure, and controlling an air flow of outside air external to the enclosure taken into the electronic equipment housing enclosure, flowing from the inlet to the outlet; and
a second opening-closing mechanism unit being provided on the outlet and controlling an air flow of inside air internal to the enclosure, flowing out from the outlet to outside the enclosure,
the control program causing a computer to perform control of adjusting motive power of the blowing unit, a degree of opening of the first opening-closing mechanism unit, and a degree of opening of the second opening-closing mechanism unit in accordance with the outside-air temperature measured by the outside-air temperature sensor and the electronic equipment power consumption measured by the power sensor.
